(19) United States
(12) Patent Application Publication
(10) Pub. No.: US 2026/0016747 A1
(43) Pub. Date: Jan. 15, 2026

(54) RESIST COMPOSITION AND METHOD OF FORMING PATTERN BY USING THE SAME

(71) Applicant: Samsung Electronics Co., Ltd., Suwon-si (KR)

(72) Inventors: Mijeong KIM, Suwon-si (KR); Kyuhyun IM, Suwon-si (KR); Minyoung HA, Suwon-si (KR)

(73) Assignee: Samsung Electronics Co., Ltd., Suwon-si (KR)

(21) Appl. No.: 19/016,424

(22) Filed: Jan. 10, 2025

(30) Foreign Application Priority Data
Jul. 12, 2024 (KR) 10-2024-0092579

(51) Int. Cl. G03F 7/004; G03F 7/027

(52) U.S. Cl. CPC G03F 7/0042; G03F 7/0048; G03F 7/027

(57) ABSTRACT

Provided are a resist composition and a method of manufacturing a pattern by using the same, the resist film including an organometallic compound represented by Formula 1, and a solvent including a polar aprotic solvent:

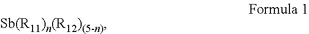

wherein R₁₁, R₁₂, and n in Formula 1 are as defined in the specification.

### CROSS-REFERENCE TO RELATED APPLICATION

This application is based on and claims priority under 35 U.S.C. § 119 to Korean Patent Application No. 10-2024-0092579, filed on Jul. 12, 2024, in the Korean Intellectual Property Office, the disclosure of which is incorporated by reference herein in its entirety.

### BACKGROUND

### 1. Field

The inventive concepts relate to resist compositions and methods of forming a pattern by using the same.

### 2. Description of the Related Art

During the manufacturing of semiconductors, resists having physical properties that change in response to light are used to form fine patterns. Among these resists, chemically amplified resists have been widely used. In chemically amplified resists, acids formed when light (e.g, incident light having a particular intensity and/or wavelength) reacts with photoacid generators react again with base resins to change the solubility of the base resins in developers, thereby enabling patterning.

### SUMMARY

Some example embodiments provide a resist composition which has improved storage stability, wherein the resist composition is configured to change one or more physical properties even by exposure to incident light at a low dose (e.g., exposure to a small amount and/or intensity of light), where the resist composition is configured to provide a pattern with improved resolution. Some example embodiments provide a method of forming a pattern by using the resist composition. Such a resist composition may be configured to change physical properties composition which has improved storage stability, wherein the resist composition is configured to change one or more physical properties even by exposure to incident light (e.g., high-energy rays), in order to overcome limitations of chemically amplified resists which may cause a formed acid to diffuse to an unexposed region, such that the resist composition reduces, minimizes, or prevents the likelihood of as a reduction in uniformity of patterns or an increase in surface roughness based on avoiding such formed acid diffusion, while simultaneously providing improved resist composition chemical stability (and thereby reduced, minimized, or prevented risk of chemical deterioration) in normal usage environments at room temperature and/or while simultaneously changing physical properties even by exposure to a small amount (e.g., small intensity) of incident light (e.g., high-energy rays).

Additional aspects will be set forth in part in the description which follows and, in part, will be apparent from the description, or may be learned by practice of the presented embodiments of the inventive concepts.

According to some example embodiments of the inventive concepts, a resist composition includes an organometallic compound represented by Formula 1 below, and a solvent including a polar aprotic solvent:

Sb(R₁₁)ₙ(R₁₂)₍₅₋ₙ₎, Formula 1
wherein R₁₁ is a linear, branched, or cyclic monovalent C₁-C₃₀ hydrocarbon group having an acid dissociation constant (pKa) of 4.5 or less and optionally containing one or more heteroatoms,
R₁₂ is a linear, branched, or cyclic C₁-C₃₀ monovalent hydrocarbon group optionally containing one or more heteroatoms, and
n is an integer from 1 to 5.

In Formula 1, R₁₁ may have an acid dissociation constant (pKa) of 0 or less.

In Formula 1, R₁₁ may be represented by *-(L₁₁)ₐ₁₁-X₁₁, R₁₂ may be represented by *-(L₁₂)ₐ₁₂-X₁₂, L₁₁ may be O, S, C═O, S═O, P═O, SO₂, PO₂, or PO₃, L₁₂ may be CRₐR_{b}, O, S, C—O, S—O, P═O, SO₂, PO₂, or PO₃, a11 may be an integer from 1 to 3, a12 may be an integer from 0 to 3, X₁₁ and X₁₂ may each independently be a substituted or unsubstituted C₁-C₃₀ alkyl group, a substituted or unsubstituted C₁-C₃₀ halogenated alkyl group, a substituted or unsubstituted C₁-C₃₀ alkoxy group, a substituted or unsubstituted C₁-C₃₀ alkylthio group, a substituted or unsubstituted C₁-C₃₀ halogenated alkoxy group, a substituted or unsubstituted C₁-C₃₀ halogenated alkylthio group, a substituted or unsubstituted C₃-C₃₀ cycloalkyl group, a substituted or unsubstituted C₃-C₃₀ cycloalkoxy group, a substituted or unsubstituted C₃-C₃₀ cycloalkylthio group, a substituted or unsubstituted C₃-C₃₀ heterocycloalkyl group, a substituted or unsubstituted C₃-C₃₀ heterocycloalkoxy group, a substituted or unsubstituted C₃-C₃₀ heterocycloalkylthio group, a substituted or unsubstituted C₂-C₃₀ alkenyl group, a substituted or unsubstituted C₂-C₃₀ alkenyloxy group, a substituted or unsubstituted C₂-C₃₀ alkenylthio group, a substituted or unsubstituted C₃-C₃₀ cycloalkenyl group, a substituted or unsubstituted C₃-C₃₀ cycloalkenyloxy group, a substituted or unsubstituted C₃-C₃₀ cycloalkenylthio group, a substituted or unsubstituted C₃-C₃₀ heterocycloalkenyl group, a substituted or unsubstituted C₃-C₃₀ heterocycloalkenyloxy group, a substituted or unsubstituted C₃-C₃₀ heterocycloalkenylthio group, a substituted or unsubstituted C₂-C₃₀ alkynyl group, a substituted or unsubstituted C₂-C₃₀ alkynyloxy group, a substituted or unsubstituted C₂-C₃₀ alkynylthio group, a substituted or unsubstituted C₆-C₃₀ aryl group, a substituted or unsubstituted C₆-C₃₀ aryloxy group, a substituted or unsubstituted C₆-C₃₀ arylthio group, a substituted or unsubstituted C₁-C₃₀ heteroaryl group, a substituted or unsubstituted C₁-C₃₀ heteroaryloxy group, or a substituted or unsubstituted C₁-C₃₀ heteroarylthio group,

Rₐ and R_{b} are each independently hydrogen, deuterium, a hydroxyl group, a cyano group, a nitro group, a substituted or unsubstituted C₁-C₃₀ alkyl group, a substituted or unsubstituted C₁-C₃₀ alkoxy group, a substituted or unsubstituted C₁-C₃₀ alkylthio group, a substituted or unsubstituted C₃-C₃₀ cycloalkyl group, a substituted or unsubstituted C₃-C₃₀ cycloalkoxy group, or a substituted or unsubstituted C₃-C₃₀ cycloalkylthio group, and * may be a binding site with an adjacent atom of Formula 1.

In Formula 1, L₁₁ may be O, S, C═O, or S═O, and L₁₂ may be CRₐR_{b}, O, S, C═O, or S═O, wherein Rₐ and R_{b} may each independently be hydrogen, deuterium, a hydroxyl group, a cyano group, a nitro group, a substituted or unsubstituted C₁-C₃₀ alkyl group, a substituted or unsubstituted C₁-C₃₀ alkoxy group, a substituted or unsubstituted C₁-C₃₀ alkylthio group, a substituted or unsubstituted C₃-C₃₀ cycloalkyl group, a substituted or unsubstituted C₃-C₃₀ cycloalkoxy group, or a substituted or unsubstituted C₃-C₃₀ cycloalkylthio group.

In Formula 1, (L₁₁)ₐ₁₁ may be O, O(C═O), or O(C═O) O, and (L₁₂)ₐ₁₂ may be a single bond, CRₐR_{b}, O, C═O, O(C═O), or O(C═O) O, wherein Rₐ and R_{b} may each independently be hydrogen, deuterium, a hydroxyl group, a cyano group, a nitro group, a substituted or unsubstituted C₁-C₃₀ alkyl group, a substituted or unsubstituted C₁-C₃₀ alkoxy group, a substituted or unsubstituted C₁-C₃₀ alkylthio group, a substituted or unsubstituted C₃-C₃₀ cycloalkyl group, a substituted or unsubstituted C₃-C₃₀ cycloalkoxy group, or a substituted or unsubstituted C₃-C₃₀ cycloalkylthio group.

In Formula 1, X₁₁ and X₁₂ may each independently be a C₁-C₃₀ alkyl group, a C₃-C₃₀ cycloalkyl group, a C₃-C₃₀ heterocycloalkyl group, a C₂-C₃₀ alkenyl group, a C₃-C₃₀ cycloalkenyl group, a C₃-C₃₀ heterocycloalkenyl group, a C₂-C₃₀ alkynyl group, a C₆-C₃₀ aryl group, a C₇-C₃₀ arylalkyl group, a C₁-C₃₀ heteroaryl group, or a C₂-C₃₀ heteroarylalkyl group. Each of the C₁-C₃₀ alkyl group, the C₃-C₃₀ cycloalkyl group, the C₃-C₃₀ heterocycloalkyl group, the C₂-C₃₀ alkenyl group, the C₃-C₃₀ cycloalkenyl group, the C₃-C₃₀ heterocycloalkenyl group, the C₂-C₃₀ alkynyl group, the C₆-C₃₀ aryl group, the C₇-C₃₀ arylalkyl group, the C₁-C₃₀ heteroaryl group, and the C₂-C₃₀ heteroarylalkyl group may be unsubstituted or substituted with deuterium, a halogen, a cyano group, a nitro group, a hydroxyl group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₅-C₂₀ cycloalkoxy group, a C₃-C₂₀ cycloalkylthio group, a C₆-C₂₀ aryl group, a C₁-C₂₀ heteroaryl group, a C₆-C₂₀ aryloxy group, a C₆-C₂₀ arylthio group, a C₁-C₂₀ heteroaryloxy group, a C₁-C₂₀ heteroarylthio group, or any combination thereof.

In Formula 1, X₁₁ may include at least one halogen.

In Formula 1, X₁₁ may be a C₁-C₃₀ alkyl group, a C₃-C₃₀ cycloalkyl group, a C₂-C₃₀ alkenyl group, a C₃-C₃₀ cycloalkenyl group, a C₂-C₃₀ alkynyl group, a C₆-C₃₀ aryl group, or a C₇-C₃₀ arylalkyl group. Each of the C₁-C₃₀ alkyl group, the C₃-C₃₀ cycloalkyl group, the C₂-C₃₀ alkenyl group, the C₃-C₃₀ cycloalkenyl group, the C₂-C₃₀ alkynyl group, the C₆-C₃₀ aryl group, and the C₇-C₃₀ arylalkyl group may be substituted with a halogen, a C₁—C₂₀ halogenated alkyl group, a C₁-C₂₀ halogenated alkoxy group, a C₁-C₂₀ halogenated alkylthio group, or any combination thereof.

The organometallic compound represented by Formula 1 may be represented by Formula 1-1:

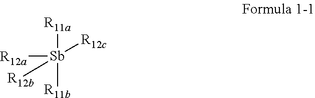

wherein, in Formula 1-1, R₁₁ₐ and R_{11b} may each independently be a linear, branched, or cyclic monovalent C₁-C₃₀ hydrocarbon group having an acid dissociation constant (pKa) of 4.5 or less and optionally containing one or more heteroatoms, and R₁₂ₐ, R_{12b}, and R_{12c} may each independently be a linear, branched, or cyclic C₁-C₃₀ monovalent hydrocarbon group optionally containing one or more heteroatoms.

The organometallic compound represented by Formula 1 may be selected from Group I:

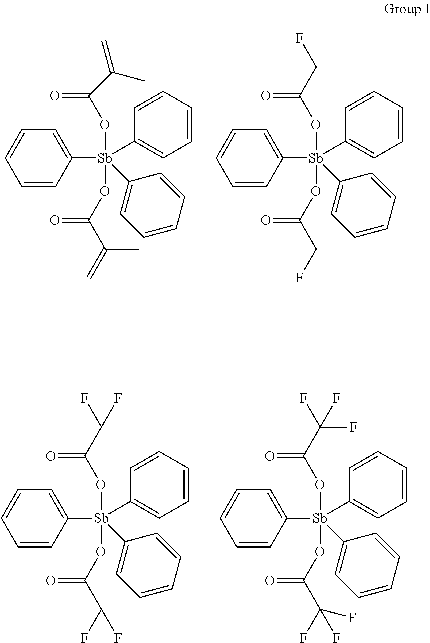

A temperature at which a mass of a sample of the organometallic compound becomes 95% of an initial mass of the sample of the organometallic compound may be 180° C. or more.

The resist composition may have a deterioration ratio of 10% or less after storage of the resist composition at a temperature of 40° C. for 3 weeks.

The solvent may include an ether-based solvent, a ketone-based solvent, an amide-based solvent, an ester-based solvent, a sulfoxide-based solvent, or any combination thereof.

The solvent may include a chain ketone-based solvent, a cyclic ketone-based solvent, a polyhydric alcohol-containing ether carboxylate-based solvent, a lactone-based solvent, an acetate ester-based solvent, or any combination thereof.

The solvent may include cyclopentanone, cyclohexanone, cycloheptanone, propylene glycol monomethyl ether acetate, propylene glycol monoethyl ether acetate, propylene glycol monopropyl ether acetate, propylene glycol monobutyl ether acetate, or any combination thereof.

The resist composition may substantially not comprise any water or any polar protic organic solvent.

According to some example embodiments, a method of forming a pattern may include: applying the resist composition on a substrate to form a resist film, exposing at least a portion of the resist film to high-energy rays to form an exposed resist film, and developing the exposed resist film based on using a developer.

The exposing may be performed based on irradiating deep ultraviolet (DUV) rays, extreme ultraviolet (EUV) rays, and/or electron beams (EBs).

The organometallic compound may undergo a condensation reaction based on the exposing of at least the portion of the resist film.

Based on the exposing at least the portion of the resist film, the exposed resist film may include an exposed portion and an unexposed portion. The developing the exposed resist film may include removing the unexposed portion.

According to some example embodiments of the inventive concepts, a method of forming a pattern includes applying the above-described resist composition to form a resist film, exposing at least a portion of the resist film to high-energy rays, and developing the exposed resist film by using a developer.

### BRIEF DESCRIPTION OF THE DRAWINGS

The above and other aspects, features, and advantages of certain embodiments will be more apparent from the following description taken in conjunction with the accompanying drawings, in which:

FIG. 1 is a flowchart illustrating a method of forming a pattern, according to some example embodiments;

FIGS. 2A, 2B, and 2C are side cross-sectional views illustrating a method of forming a pattern, according to some example embodiments;

FIGS. 3A, 3B, 3C, 3D, and 3E are cross-sectional side views illustrating a method of forming a patterning structure, according to some example embodiments;

FIGS. 4A, 4B, 4C, 4D, and 4E are side cross-sectional views illustrating a method of forming a semiconductor device, according to some example embodiments;

FIGS. 5A, 5B, 5C, and 5D are diagrams showing thermogravimetric analysis (TGA) data of Sb-1, Sb-2, Sb-3, and M-01, respectively;

FIG. 6A is a diagram illustrating ¹H-NMR data of Sb-1 immediately after synthesis, and FIG. 6B is a diagram illustrating ¹H-NMR data of Sb-1 after storage in a solid state at room temperature for 20 days;

FIG. 6C is a diagram illustrating ¹H-NMR data of M-01 immediately after synthesis, and FIG. 6D is a diagram illustrating ¹H-NMR data of M-01 after storage in a solid state at room temperature for 20 days;

FIGS. 7A, 7B, and 7C are graphs showing relative intensities of gel permeation chromatography (GPC) spectra according to storage periods of Sb-1, Sb-2, and Sb-3, respectively, wherein FIG. 7A is a graph showing values of Examples 1-1 to 1-4 and Comparative Examples 1-1 to 1-4, FIG. 7B is a graph showing values of Examples 2-1 to 2-4 and Comparative Examples 2-1 to 2-4, and FIG. 7C is a graph showing values of Comparative Examples 3-1 to 3-4 and Comparative Examples 4-1 to 4-4; and

FIG. 8A is a graph showing a change in film thickness after development according to dose of Examples 6-1 and 6-2, and FIG. 8B is a graph showing a change in film thickness after development according to dose of Comparative Examples 6-1 and 6-2.

### DETAILED DESCRIPTION

Reference will now be made in detail to example embodiments, some of which are illustrated in the accompanying drawings, wherein like reference numerals refer to like elements throughout. In this regard, some example embodiments may have different forms and should not be construed as being limited to the descriptions set forth herein. Accordingly, some example embodiments are merely described below, by referring to the drawings, to explain aspects thereof. As used herein, the term “and/or” includes any and all combinations of one or more of the associated listed items. Expressions such as “at least one of,” when preceding a list of elements, modify the entire list of elements and do not modify the individual elements of the list.

Since the inventive concepts can apply various transformations and have various embodiments, specific embodiments will be illustrated in the drawings and described in detail in the detailed description. However, it should be understood that this is not intended to limit the inventive concepts to specific embodiments, and includes all transformations, equivalents, and substitutes included in the spirit and scope of the inventive concepts. In describing the inventive concepts, when it is determined that the specific description of the known related art unnecessarily obscures the gist of the inventive concepts, the detailed description thereof will be omitted.

The use of the term “the” and similar demonstratives may correspond to both the singular and the plural. Operations constituting methods may be performed in any suitable order unless otherwise indicated herein or otherwise clearly contradicted by context, and are not necessarily limited to the stated order.

The use of all illustrations or illustrative terms in some example embodiments is simply to describe the technical ideas in detail, and the scope of the present inventive concepts is not limited by the illustrations or illustrative terms unless they are limited by claims.

Regardless of whether elements and/or properties thereof are modified as “substantially,” it will be understood that these elements and/or properties thereof should be construed as including a manufacturing or operational tolerance (e.g., +10%) around the stated elements and/or properties thereof.

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

As described herein, when an operation is described to be performed, or an effect such as a structure is described to be established “by” or “through” performing additional operations, it will be understood that the operation may be performed and/or the effect/structure may be established “based on” the additional operations, which may include performing said additional operations alone or in combination with other further additional operations.

It will be understood that, although the terms “first,” “second,” and “third” may be used herein to describe various elements, these elements should not be limited by these terms. These terms are only used to distinguish one element from another element and not used to limit order or types of elements.

In the present specification, when a portion of a layer, film, region, plate, or the like is described as being “on” or “above” another portion, it may include not only the meaning of “immediately on/under/to the left/to the right in a contact manner,” but also the meaning of “on/under/to the left/to the right in a non-contact manner.”

An expression used in the singular encompasses the expression of the plural, unless it has a clearly different meaning in the context. Hereinafter, unless explicitly described to the contrary, it is to be understood that the terms such as “including,” “having,” and “comprising” are intended to indicate the existence of the features, numbers, steps, actions, components, parts, ingredients, materials, or any combinations thereof disclosed in the specification and are not intended to preclude the possibility that one or more other features, numbers, steps, actions, components, parts, ingredients, materials, or any combinations thereof may exist or may be added.

Whenever a range of values is recited, the range includes all values that fall within the range as if expressly written, and the range further includes the boundaries of the range. Thus, a range of “X to Y” includes all values between X and Y and also includes X and Y.

As used herein, “Cₓ-C_{y}” or “Cx to Cy” means that a number (e.g., quantity) of carbons constituting a substituent is x to y, wherein x and y may each be any natural number. For example, “C₁-C₆” and “C1 to C6” means that a number of carbons constituting the substituent is 1 to 6, and “C₆-C₂₀” and C6 to C20″ means that a number of carbons constituting the substituent is 6 to 20.

As used herein, the term “monovalent hydrocarbon group” may refer to a monovalent residue derived from an organic compound including carbon and hydrogen or a derivative thereof, and specific examples thereof may include linear or branched alkyl groups (for example, a methyl group, an ethyl group, a propyl group, an isopropyl group, a butyl group, an isobutyl group, a sec-butyl group, a tert-butyl group, a pentyl group, a neopentyl group, a hexyl group, a heptyl group, a 2-ethylhexyl group, and a nonyl group); monovalent saturated cycloaliphatic hydrocarbon groups (cycloalkyl groups) (for example, a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a 1-adamantyl group, a 2-adamantyl group, a 1-adamantylmethyl group, a norbornyl group, a norbornylmethyl group, a tricyclodecanyl group, a tetracyclododecanyl group, a tetracyclododecanylmethyl group, and a dicyclohexylmethyl group); monovalent unsaturated aliphatic hydrocarbon groups (alkenyl group and alkynyl group) (for example, an allyl group); a monovalent unsaturated cycloaliphatic hydrocarbon group (cycloalkenyl group) (for example, 3-cyclohexenyl); aryl groups (for example, a phenyl group, a 1-naphthyl group, and a 2-naphthyl group); arylalkyl groups (for example, a benzyl group and a diphenylmethyl group); heteroatom-containing monovalent hydrocarbon groups (for example, a tetrahydrofuranyl group, a methoxymethyl group, an ethoxymethyl group, a methylthiomethyl group, an acetamidemethyl group, a trifluoroethyl group, a (2-methoxyethoxy)methyl group, an acetoxymethyl group, a 2-carboxy-1-cyclohexyl group, a 2-oxopropyl group, a 4-oxo-1-adamantyl group, and a 3-oxocyclohexyl group); or any combination thereof. In addition, in these groups, some hydrogen atoms may be substituted by a moiety including one or more heteroatoms such as oxygen, sulfur, nitrogen, phosphorus, or a halogen atom, or some carbon atoms may be substituted by a moiety including one or more heteroatoms such as oxygen, sulfur, nitrogen, or phosphorus so that these groups may include a cyano group, a nitro group, a hydroxyl group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, and the like.

As used herein, the term “divalent hydrocarbon group” is a divalent residue and means that any one hydrogen atom of the monovalent hydrocarbon group is replaced with a binding site with an adjacent atom. The divalent hydrocarbon group may include, for example, a linear or branched alkylene group, a cycloalkylene group, an alkenylene group, an alkynylene group, a cycloalkenylene group, an arylene group, a group in which some carbon atoms thereof are replaced with a heteroatom, and the like.

As used herein, the term “alkyl group” refers to a linear or branched saturated aliphatic hydrocarbon monovalent group, and specific examples thereof include a methyl group, an ethyl group, a propyl group, an isobutyl group, a sec-butyl group, a tert-butyl group, a pentyl group, an iso-amyl group, a hexyl group, and the like. As used herein, the term “alkylene group” refers to a linear or branched saturated aliphatic hydrocarbon divalent group, and specific examples thereof include a methylene group, an ethylene group, a propylene group, a butylene group, an isobutylene group, and the like.

As used herein, the term “halogenated alkyl group” refers to a group in which one or more hydrogen of an alkyl group are substituted with halogen, and specific examples thereof include CF₃ and the like. Here, a halogen is F, Cl, Br, or I.

As used herein, the term “alkoxy group” refers to a monovalent group having a formula of —OA₁₀₁, wherein A₁₀₁ is an alkyl group. Specific examples thereof include a methoxy group, an ethoxy group, an isopropyloxy group, and the like.

As used herein, the term “alkylthio group” refers to a monovalent group having a formula of —SA₁₀₁, wherein A₁₀₁ is an alkyl group.

As used herein, the term “halogenated alkoxy group” refers to a group in which one or more hydrogen atoms of an alkoxy group are substituted with halogen, and specific examples thereof include —OCF₃ and the like.

As used herein, the term “halogenated alkylthio group” refers to a group in which one or more hydrogen atoms of an alkylthio group are substituted with halogen, and specific examples thereof include —SCF₃ and the like.

As used herein, the term “cycloalkyl group” refers to a monovalent saturated hydrocarbon cyclic group, and specific examples thereof include monocyclic groups such as a cyclopropyl group, a cyclobutyl group, a cyclopentyl group, a cyclohexyl group, and a cycloheptyl group, and polycyclic condensed cyclic groups such as a norbornyl group and an adamantyl group. As used herein, the term “cycloalkylene group” refers to a divalent saturated hydrocarbon cyclic group, and specific examples thereof include a cyclopentylene group, a cyclohexylene group, an adamantylene group, an adamantylmethylene group, a norbornylene group, a norbornylmethylene group, a tricyclodecanylene group, a tetracyclododecanylene group, a tetracyclododecanylmethylene group, a dicyclohexylmethylene group, and the like.

As used herein, the term “cycloalkoxy group” refers to a monovalent group having a formula of-OA₁₀₂, wherein A₁₀₂ is a cycloalkyl group. Specific examples thereof include a cyclopropoxy group, a cyclobutoxy group, and the like.

As used herein, the term “cycloalkylthio group” refers to a monovalent group having a formula of-SA₁₀₂, wherein A₁₀₂ is a cycloalkyl group.

As used herein, the term “heterocycloalkyl group” may be a group in which some carbon atoms of the cycloalkyl group are replaced by a moiety including a heteroatom, for example, oxygen, sulfur, or nitrogen, and specifically, the heterocycloalkyl group may include an ether bond, an ester bond, a sulfonate ester bond, carbonate, a lactone ring, a sultone ring, or a carboxylic anhydride moiety. As used herein, the term “heterocycloalkylene group” is a group in which some carbon atoms of the cycloalkylene group are replaced by a moiety including a heteroatom, for example, oxygen, sulfur, or nitrogen.

As used herein, the term “heterocycloalkoxy group” refers to a monovalent group having a formula of-OA₁₀₃, wherein A₁₀₃ is a heterocycloalkyl group.

As used herein, the term “heterocycloalkylthio group” refers to a monovalent group having a chemical formula of-SA₁₀₃, wherein A₁₀₃ is a heterocycloalkyl group.

As used herein, the term “alkenyl group” refers to a linear or branched unsaturated aliphatic hydrocarbon monovalent group including one or more carbon-carbon double bonds. As used herein, the term “alkenylene group” refers to a linear or branched unsaturated aliphatic hydrocarbon divalent group including one or more carbon-carbon double bonds.

The term “alkenyloxy group” as used herein refers to a monovalent group having a formula of-OA₁₀₄, wherein A₁₀₄ is an alkenyl group.

As used herein, the term “cycloalkenyl group” refers to a monovalent unsaturated hydrocarbon cyclic group including one or more carbon-carbon double bonds. As used herein, the term “cycloalkenylene group” refers to a divalent unsaturated hydrocarbon cyclic group including one or more carbon-carbon double bonds.

The term “cycloalkenyloxy group” as used herein refers to a monovalent group having a formula of-OA₁₀₅, where A₁₀₅ is a cycloalkenyl group.

As used herein, the term “heterocycloalkenyl group” is a group in which some carbon atoms of the cycloalkenylene group are replaced by a moiety including one or more heteroatoms, for example, oxygen, sulfur, or nitrogen. As used herein, the term “heterocycloalkenylene group” is a group in which some carbon atoms of the cycloalkenylene group are replaced by a moiety including one or more heteroatoms, for example, oxygen, sulfur, or nitrogen.

The term “heterocycloalkenyloxy group” as used herein refers to a monovalent group having a formula of-OA₁₀₆, wherein A₁₀₆ is a heterocycloalkenyl group.

As used herein, the term “alkynyl group” refers to a linear or branched unsaturated aliphatic hydrocarbon monovalent group including one or more carbon-carbon triple bonds.

The term “alkynyloxy group” as used herein refers to a monovalent group having a formula of-OA₁₀₇, wherein A₁₀₇ is an alkynyl group.

As used herein, the term “aryl group” refers to a monovalent group having a carbocyclic aromatic system, and specific examples thereof include a phenyl group, a naphthyl group, an anthracenyl group, a phenanthrenyl group, a pyrenyl group, a chrysenyl group, and the like. As used herein, the term “arylene group” refers to a divalent group having a carbocyclic aromatic system.

As used herein, the term “aryloxy group” refers to a monovalent group having a chemical formula of-OA₁₀₄, wherein A₁₀₄ is an aryl group.

As used herein, the term “arylthio group” refers to a monovalent group having a chemical formula of-SA₁₀₄, wherein A₁₀₄ is an aryl group.

As used herein, the term “heteroaryl group” refers to a monovalent group having a heterocyclic aromatic system, and specific examples thereof include a pyridinyl group, a pyrimidinyl group, a pyrazinyl group, and the like. As used herein, the term “heteroarylene group” refers to a divalent group having a heterocyclic aromatic system.

As used herein, the term “heteroaryloxy group” refers to a monovalent group having a chemical formula of-OA₁₀₅, wherein A₁₀₅ is a heteroaryl group.

As used herein, the term “heteroarylthio group” refers to a monovalent group having a chemical formula of-SA₁₀₅, wherein A₁₀₅ is a heteroaryl group.

As used herein, the term “arylalkyl group” refers to a group in which a monovalent group having a carbocyclic aromatic system is substituted for an alkyl group, and specific examples thereof include a benzyl group, a diphenylmethyl group, and the like.

As used herein, the term “heteroarylalkyl group” refers to a group in which a monovalent group having a heterocyclic aromatic system is substituted for an alkyl group.

In this specification, the term “heterocyclic group” refers to a C₁-C₆₀ monocyclic or polycyclic group including at least one heteroatom and is a group including all of monovalent, divalent, and trivalent groups.

In the present specification, the term “substituent” includes: deuterium, a halogen, a cyano group, a nitro group, a hydroxyl group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, or a C₁-C₂₀ heteroarylthio group; a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₅-C₂₀ cycloalkylthio group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, and a C₁-C₂₀ heteroarylthio group, each substituted with deuterium, a halogen, a cyano group, a nitro group, a hydroxyl group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₅-C₂₀ cycloalkylthio group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, or a C₁-C₂₀ heteroarylthio group, and any combination thereof; or any combination thereof.

As used herein, when a definition is not otherwise provided, “aromatic ring” refers to a functional group in which all atoms in the cyclic functional group have a p-orbital, and wherein these p-orbitals are conjugated.

Hereinafter, some example embodiments will be described in detail with reference to the accompanying drawings, wherein like reference numerals denote substantially the same or corresponding components throughout the drawings, and a redundant description thereof will be omitted. In the drawings, the thicknesses of layers and regions are exaggerated for clarity. Also, in the drawings, the thicknesses of some layers and regions are exaggerated for convenience of description. Meanwhile, some example embodiments set forth herein are merely examples and various changes may be made therein.

### [Resist Composition]

A resist composition according to some example embodiments may include an organometallic compound represented by Formula 1 below, and a solvent including a polar aprotic solvent:

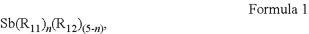

In Formula 1,
R₁₁ may be a linear, branched, or cyclic monovalent C₁-C₃₀ hydrocarbon group having an acid dissociation constant (pKa) of 4.5 or less and optionally containing one or more heteroatoms,
R₁₂ may be a linear, branched, or cyclic C₁-C₃₀ monovalent hydrocarbon group optionally containing one or more heteroatoms, and
n may be an integer from 1 to 5.

The resist composition may have (e.g., may be configured to have, may be associated with, etc.) a deterioration ratio of 10% or less, specifically, 5% or less, after storage (e.g., storage of the resist composition) at a temperature of 40° C. for 3 weeks. Here, the deterioration ratio may be a value calculated from a change ratio of relative intensity of a gel permeation chromatography (GPC) spectrum measured at a wavelength of 264 nm and may be a value obtained by subtracting a relative intensity value of a GPC spectrum of a composition (e.g., the resist composition) measured after the composition is stored for 3 weeks from a relative intensity value of a GPC spectrum of the composition measured immediately after the composition is prepared.

The solubility of the resist composition in a developer may be changed by exposure to high-energy rays. The resist composition may be a negative-type resist composition in which an unexposed portion of a resist film is dissolved and removed to form a negative-type resist pattern or may be a positive-type resist composition in which an exposed portion is dissolved and removed to form a positive-type resist pattern. The resist composition may be modified in various ways such as being a negative type or a positive type according to exposure intensity and/or a type of a developer. Specifically, the resist composition may be a negative-type resist composition.

In addition, the resist composition according to some example embodiments may be used for an alkaline developing process in which an alkaline developer is used for a developing process when a resist pattern is formed and may also be used for a solvent developing process in which an organic solvent-containing developer (hereinafter referred to as an organic developer) is used for developing treatment. Specifically, the resist composition may be used for an alkaline developing process.

Since the resist composition is non-chemically amplified, the resist composition substantially may not include a photoacid generator (e.g., the resist composition may not include any or substantially any photoacid generators).

Since the physical properties of the organometallic compound are changed by exposure (e.g., exposure to incident light, including for example high-energy rays including deep ultraviolet (DUV) rays, extreme ultraviolet (EUV) rays, electron beams (EBs), or the like), the resist composition substantially may not include a compound having a molecular weight of about 1,000 or more other than the organometallic compound. For example, the resist composition may not include any or substantially any compounds having a molecular weight of about 1,000 or more other than the organometallic compound.

In some example embodiments, when the resist composition is described to not include any or substantially any of a certain compound or to substantially not include the certain compound, the certain compound may be included in the resist composition in a proportion of the total mass of the resist composition that is between 0% and about 1%, between 0% and about 0.1%, or between 0% and about 0.01%, or the certain compound may be totally absent or omitted from the resist composition.

The organometallic compound may be prepared through any suitable method, or commercially available products may be used.

The structures (compositions) of the organometallic compound and the additive may be identified by performing Fourier transform infrared (FT-IR) analysis, nuclear magnetic resonance (NMR) analysis, fluorescence X-ray (XRF) analysis, mass spectrometry, ultraviolet (UV) analysis, single crystal X-ray structure analysis, powder X-ray diffraction (PXRD) analysis, liquid chromatography (LC) analysis, size exclusion chromatography (SEC) analysis, thermal analysis, or the like. A detailed identification method is as described in Examples.

### <Organometallic Compound>

Although not limited to a particular theory, in the organometallic compound, radicals may be formed by heat and/or high-energy rays. Specifically, the organometallic compound may be decomposed by high-energy rays, and in particular, radicals may be formed from a Sb-carbon bond of the organometallic compound. Accordingly, the physical properties of the organometallic compound, particularly, the solubility thereof in a developer, may change.

Since the organometallic compound represented by Formula 1 may include at least one R₁₁ having relatively low CH bond dissociation energy, photosensitivity of the organometallic compound, and thus photosensitivity of the resist composition, to high-energy rays, particularly, EUV, may be improved, and storage stability may be improved.

In the organometallic compound, a bond between Sb and R₁₁ may be a Sb-oxygen single bond or a Sb-sulfur single bond, and a bond between Sb and R₁₂ may be a Sb-carbon single bond.

Specifically, the bond between Sb and R₁₁ may be a Sb-oxygen single bond, and the bond between Sb and R₁₂ may be a Sb-carbon single bond.

A temperature at which a mass of a sample of the organometallic compound becomes 99% of an initial mass of the sample of the organometallic compound, T_{d} (1%, ° C.) of the organometallic compound, may be 120° C. or more (e.g., about 120° C. to about 3,000° C.). Specifically, the T_{d} (1%, ° C.) of the organometallic compound may be 140° C. or more (e.g., about 140° C. to about 3,000° C.).

A temperature at which a mass of a sample of the organometallic compound becomes 95% of an initial mass of the sample of the organometallic compound, T_{d} (5%, ° C.) of the organometallic compound, may be 180° C. or more (e.g., about 180° C. to about 3,000° C.). Specifically, the T_{d} (5%, ° C.) of the organometallic compound may be 140° C. or more (e.g., about 140° C. to about 3,000° C.).

Although not limited to a specific theory, the organometallic compound may have relatively high thermal stability and thus may not be thermally decomposed during a pattern formation process, particularly, a post application bake process.

The organometallic compound may have a molecular weight of about 3,000 g/mol or less. Specifically, the organometallic compound may have a molecular weight of about 2,000 g/mol or less.

For example, in Formula 1, R₁₁ may have an acid dissociation constant (pKa) of 0 or less.

For example, in Formula 1, R₁₁ may be represented by *-(L₁₁)ₐ₁₁-X₁₁, R₁₂ may be represented by *-(L₁₂)ₐ₁₂-X₁₂,
L₁₁ may be O, S, C═O, S═O, P═O, SO₂, PO₂, or PO₃,
L₁₂ may be CRₐR_{b}, O, S, C═O, S═O, P═O, SO₂, PO₂, or PO₃,
a11 may be an integer from 1 to 3,
a12 may be an integer from 0 to 3,
X₁₁ and X₁₂ may each independently be a substituted or unsubstituted C₁-C₃₀ alkyl group, a substituted or unsubstituted C₁-C₃₀ halogenated alkyl group, a substituted or unsubstituted C₁-C₃₀ alkoxy group, a substituted or unsubstituted C₁-C₃₀ alkylthio group, a substituted or unsubstituted C₁-C₃₀ halogenated alkoxy group, a substituted or unsubstituted C₁-C₃₀ halogenated alkylthio group, a substituted or unsubstituted C₃-C₃₀ cycloalkyl group, a substituted or unsubstituted C₃-C₃₀ cycloalkoxy group, a substituted or unsubstituted C₃-C₃₀ cycloalkylthio group, a substituted or unsubstituted C₃-C₃₀ heterocycloalkyl group, a substituted or unsubstituted C₃-C₃₀ heterocycloalkoxy group, a substituted or unsubstituted C₃-C₃₀ heterocycloalkylthio group, a substituted or unsubstituted C₂-C₃₀ alkenyl group, a substituted or unsubstituted C₂-C₃₀ alkenyloxy group, a substituted or unsubstituted C₂-C₃₀ alkenylthio group, a substituted or unsubstituted C₃-C₃₀ cycloalkenyl group, a substituted or unsubstituted C₃-C₃₀ cycloalkenyloxy group, a substituted or unsubstituted C₃-C₃₀ cycloalkenylthio group, a substituted or unsubstituted C₃-C₃₀ heterocycloalkenyl group, a substituted or unsubstituted C₃-C₃₀ heterocycloalkenyloxy group, a substituted or unsubstituted C₃-C₃₀ heterocycloalkenylthio group, a substituted or unsubstituted C₂-C₃₀ alkynyl group, a substituted or unsubstituted C₂-C₃₀ alkynyloxy group, a substituted or unsubstituted C₂-C₃₀ alkynylthio group, a substituted or unsubstituted C₆-C₃₀ aryl group, a substituted or unsubstituted C₆-C₃₀ aryloxy group, a substituted or unsubstituted C₆-C₃₀ arylthio group, a substituted or unsubstituted C₁-C₃₀ heteroaryl group, a substituted or unsubstituted C₁-C₃₀ heteroaryloxy group, or a substituted or unsubstituted C₁-C₃₀ heteroarylthio group,
Rₐ and R_{b} may each independently be hydrogen, deuterium, a hydroxyl group, a cyano group, a nitro group, a substituted or unsubstituted C₁-C₃₀ alkyl group, a substituted or unsubstituted C₁-C₃₀ alkoxy group, a substituted or unsubstituted C₁-C₃₀ alkylthio group, a substituted or unsubstituted C₃-C₃₀ cycloalkyl group, a substituted or unsubstituted C₃-C₃₀ cycloalkoxy group, or a substituted or unsubstituted C₃-C₃₀ cycloalkylthio group, and
* may be a binding site with an adjacent atom of Formula 1.

Specifically, in Formula 1, L₁₁ may be O, S, C═O, or S═O, and L₁₂ may be CRₐR_{b}, O, S, C—O, or S═O, wherein Rₐ and R_{b} are each independently hydrogen, deuterium, a hydroxyl group, a cyano group, a nitro group, a substituted or unsubstituted C₁-C₃₀ alkyl group, a substituted or unsubstituted C₁-C₃₀ alkoxy group, a substituted or unsubstituted C₁-C₃₀ alkylthio group, a substituted or unsubstituted C₃-C₃₀ cycloalkyl group, a substituted or unsubstituted C₃-C₃₀ cycloalkoxy group, or a substituted or unsubstituted C₃-C₃₀ cycloalkylthio group.

More specifically, in Formula 1, (L₁₁)ₐ₁₁ may be O, O(C═O), or O(C—O) O, and (L₁₂)ₐ₁₂ may be a single bond, CRₐR_{b}, O, C═O, O(C═O), or O(C═O) O, wherein Rₐ and R_{b} are each independently hydrogen, deuterium, a hydroxyl group, a cyano group, a nitro group, a substituted or unsubstituted C₁-C₃₀ alkyl group, a substituted or unsubstituted C₁-C₃₀ alkoxy group, a substituted or unsubstituted C₁-C₃₀ alkylthio group, a substituted or unsubstituted C₃-C₃₀ cycloalkyl group, a substituted or unsubstituted C₃-C₃₀ cycloalkoxy group, or a substituted or unsubstituted C₃-C₃₀ cycloalkylthio group.

Specifically, in Formula 1, X₁₁ and X₁₂ may each independently be selected from (e.g., may each independently be) a C₁-C₃₀ alkyl group, a C₃-C₃₀ cycloalkyl group, a C₃-C₃₀ heterocycloalkyl group, a C₂-C₃₀ alkenyl group, a C₃-C₃₀ cycloalkenyl group, a C₃-C₃₀ heterocycloalkenyl group, a C₂-C₃₀ alkynyl group, a C₆-C₃₀ aryl group, a C₇-C₃₀ arylalkyl group, a C₁-C₃₀ heteroaryl group, or a C₂-C₃₀ heteroarylalkyl group, and each of the C₁-C₃₀ alkyl group, the C₃-C₃₀ cycloalkyl group, the C₃-C₃₀ heterocycloalkyl group, the C₂-C₃₀ alkenyl group, the C₃-C₃₀ cycloalkenyl group, the C₃-C₃₀ heterocycloalkenyl group, the C₂-C₃₀ alkynyl group, the C₆-C₃₀ aryl group, the C₇-C₃₀ arylalkyl group, the C₁-C₃₀ heteroaryl group, and the C₂-C₃₀ heteroarylalkyl group may be unsubstituted or substituted with deuterium, a halogen, a cyano group, a nitro group, a hydroxyl group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₅-C₂₀ cycloalkoxy group, a C₅-C₂₀ cycloalkylthio group, a C₆-C₂₀ aryl group, a C₁-C₂₀ heteroaryl group, a C₆-C₂₀ aryloxy group, a C₆-C₂₀ arylthio group, a C₁-C₂₀ heteroaryloxy group, a C₁-C₂₀ heteroarylthio group, or any combination thereof.

More specifically, in Formula 1, X₁₁ and X₁₂ may each independently be selected from (e.g., may each independently be) a C₁-C₃₀ alkyl group, a C₃-C₃₀ cycloalkyl group, a C₂-C₃₀ alkenyl group, a C₃-C₃₀ cycloalkenyl group, a C₂-C₃₀ alkynyl group, a C₆-C₃₀ aryl group, and a C₇-C₃₀ arylalkyl group, and each of the C₁-C₃₀ alkyl group, the C₃-C₃₀ cycloalkyl group, the C₂-C₃₀ alkenyl group, the C₃-C₃₀ cycloalkenyl group, the C₂-C₃₀ alkynyl group, the C₆-C₃₀ aryl group, and the C₇-C₃₀ arylalkyl group may be unsubstituted or substituted with deuterium, a halogen, a cyano group, a nitro group, a hydroxyl group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₁-C₂₀ heteroaryl group, a C₆-C₂₀ aryloxy group, a C₆-C₂₀ arylthio group, a C₁-C₂₀ heteroaryloxy group, a C₁-C₂₀ heteroarylthio group, or any combination thereof.

In particular, in Formula 1, X₁₁ and X₁₂ may each independently be selected from (e.g., may each independently be) any one of Formulas 3-1 to 3-21 below:

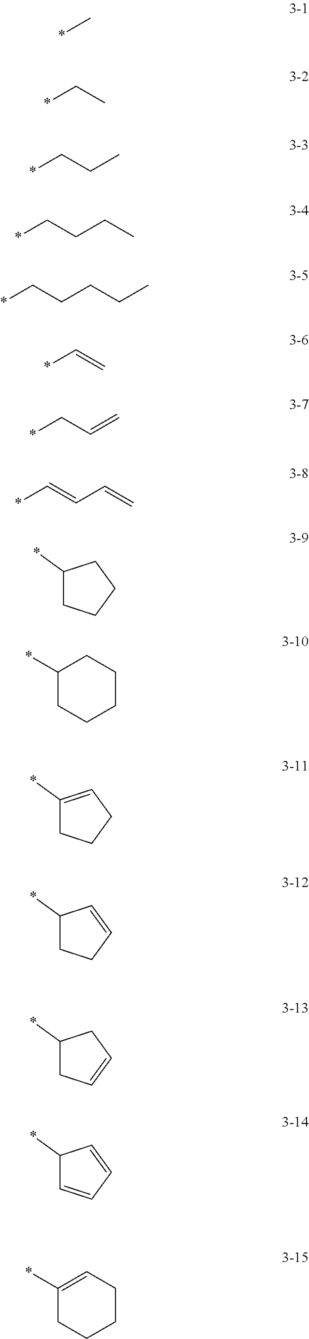

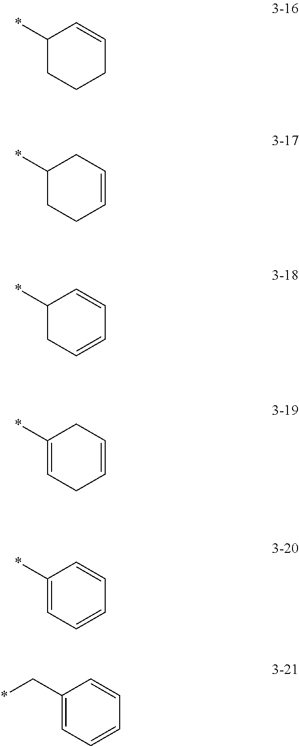 [SMILES: *C1C=CCCC1 ; *C1CC=CCC1 ; *C1C=CC=CC1 ; *C1=CCC=CC1 ; *c1ccccc1 ; *Cc1ccccc1]

In Formulas 3-1 to 3-21, at least one hydrogen atom may be optionally substituted with deuterium, a halogen, a cyano group, a nitro group, a hydroxyl group, a thiol group, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group. or any combination thereof, and * may be a binding site with an adjacent atom of Formula 1.

In some example embodiments, in Formula 1, X₁₁ may include at least one halogen.

In some example embodiments, in Formula 1, X₁₁ may be selected from (e.g., may be) a C₁-C₃₀ alkyl group, a C₃-C₃₀ cycloalkyl group, a C₂-C₃₀ alkenyl group, a C₃-C₃₀ cycloalkenyl group, a C₂-C₃₀ alkynyl group, a C₆-C₃₀ aryl group, and a C₇-C₃₀ arylalkyl group, and each of the C₁-C₃₀ alkyl group, the C₃-C₃₀ cycloalkyl group, the C₂-C₃₀ alkenyl group, the C₃-C₃₀ cycloalkenyl group, the C₂-C₃₀ alkynyl group, the C₆-C₃₀ aryl group, and the C₇-C₃₀ arylalkyl group may be substituted with a halogen, a C₁-C₂₀ halogenated alkyl group, a C₁-C₂₀ halogenated alkoxy group, a C₁-C₂₀ halogenated alkylthio group, or any combination thereof.

For example, in Formula 1, n may be 2.

In some example embodiments, the organometallic compound represented by Formula 1 may be represented by Formula 1-1 below:

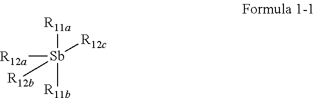

In Formula 1-1,
R₁₁ₐ and R_{11b} may each be defined as for R₁₁ in Formula 1, for example such that R₁₁ₐ and R_{11b} may each independently be a linear, branched, or cyclic monovalent C₁-C₃₀ hydrocarbon group having an acid dissociation constant (pKa) of 4.5 or less and optionally containing one or more heteroatoms, and
R₁₂ₐ, R_{12b}, and R_{12c} may each be defined as for R₁₂ in Formula 1, for example such that R₁₂ₐ, R_{12b}, and R_{12c} may each independently be a linear, branched, or cyclic C₁-C₃₀ monovalent hydrocarbon group optionally containing one or more heteroatoms.

In some example embodiments, the organometallic compound represented by Formula 1 may be selected from Group I below (e.g., may be one of the compounds of Group I below):

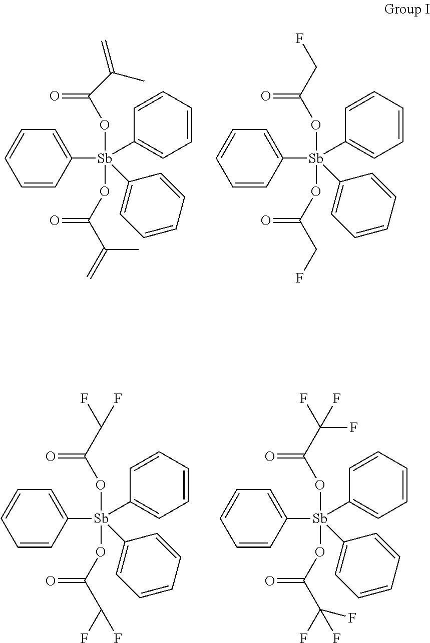

The organometallic compound may be any one type represented by Formula 1, or two or more types of organometallic compounds may be mixed and used. For example, in some example embodiments the resist composition may include two or more organometallic compounds which may be different than each other and may each independently be represented by Formula 1.

In the resist composition, the organometallic compound may be included in a range of about 0.01 parts by weight to about 100 parts by weight, specifically, about 0.2 parts by weight or more, about 0.5 parts by weight or more, about 1 part by weight or more, about 1.5 parts by weight or more, about 90 parts by weight or less, about 80 parts by weight or less, about 0.01 parts by weight to about 90 parts by weight, about 0.01 parts by weight to about 80 parts by weight, about 0.2 parts by weight to about 90 parts by weight, about 0.2 parts by weight to about 80 parts by weight, about 0.5 parts by weight to about 90 parts by weight, about 0.5 parts by weight to about 80 parts by weight, about 1 part by weight to about 90 parts by weight, about 1 part by weight to about 80 parts by weight, about 1.5 parts by weight to about 90 parts by weight, or about 1.5 parts by weight to about 80 parts by weight, with respect to 100 parts by weight of the resist composition. When the above range is satisfied, while a chemical bond between organometallic compounds is sufficiently formed, side reactions may be suppressed, thereby providing a resist composition with improved sensitivity and/or resolution.

### <Solvent>

In some example embodiments, the solvent may include at least one selected from (e.g., at least one of) an ether-based solvent, a ketone-based solvent, an amide-based solvent, an ester-based solvent, a sulfoxide-based solvent, or any combination thereof.

Specifically, the solvent may include at least one selected from (e.g., at least one of) a ketone-based solvent, an ester-based solvent, or any combination thereof.

Examples of the ether-based solvent may include, but are not limited to: diethylene glycol dimethyl ether; dipropylene glycol dimethyl ether, a dialkyl ether-based solvent such as diethyl ether, dipropyl ether, or dibutyl ether; a cyclic ether-based solvent such as 1,4-dioxane, tetrahydrofuran, or tetrahydropyran; and an aromatic ring-containing ether-based solvent such as diphenyl ether or anisole.

Examples of the ketone-based solvent may include: a chain ketone-based solvent such as acetone, methyl ethyl ketone, methyl n-propyl ketone, methyl n-butyl ketone, diethyl ketone, methyl iso-butyl ketone, 2-heptanone, ethyl-n-butyl ketone, methyl-n-hexyl ketone, diisobutyl ketone, or trimethylnonanone; a cyclic ketone-based solvent such as cyclopentanone, cyclohexanone, cycloheptanone, cyclooctanone, methylcyclohexanone; 2,4-pentanedione, acetonyl acetone, and acetophenone.

Examples of the amide-based solvent may include: a cyclic amide-based solvent such as N,N′-dimethylimidazolidinone or N-methyl-2-pyrrolidone; and a chain amide-based solvent such as N-methylformamide, N,N-dimethylformamide, N,N-diethylformamide, acetamide, N-methylacetamide, N,N-dimethylacetamide, or N-methylpropionamide.

Examples of the ester-based solvent may include: an acetate ester-based solvent such as methyl acetate, ethyl acetate, n-propyl acetate, isopropyl acetate, n-butyl acetate, isobutyl acetate, sec-butyl acetate, t-butyl acetate, n-pentyl acetate, isopentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, or n-nonyl acetate; a polyhydric alcohol-containing ether carboxylate-based solvent such as ethylene glycol monomethyl ether acetate, ethylene glycol monoethyl ether acetate, diethylene glycol monomethyl ether acetate, diethylene glycol monoethyl ether acetate, diethylene glycol mono-n-butyl ether acetate, propylene glycol monomethyl ether acetate (PGMEA), propylene glycol monoethyl ether acetate, propylene glycol monopropyl ether acetate, propylene glycol monobutyl ether acetate, dipropylene glycol monomethyl ether acetate, or dipropylene glycol monoethyl ether acetate; a lactone-based solvent such as γ-butyrolactone (GBL) or δ-valerolactone; a carbonate-based solvent such as dimethyl carbonate, diethyl carbonate, ethylene carbonate, or propylene carbonate; and ethylene glycol diacetate, methoxytriglycol acetate, ethyl propionate, n-butyl propionate, isoamyl propionate, diethyloxalate, di-n-butyloxalate, methyl acetoacetate, ethyl acetoacetate, diethyl malonate, dimethyl phthalate, or diethyl phthalate.

Examples of the sulfoxide-based solvent may include dimethyl sulfoxide, diethyl sulfoxide, and the like.

Specifically, the solvent may include a chain ketone-based solvent, a cyclic ketone-based solvent, a polyhydric alcohol-containing ether carboxylate-based solvent, a lactone-based solvent, an acetate ester-based solvent, or any combination thereof.

More specifically, the solvent may include a cyclic ketone-based solvent, a polyhydric alcohol-containing ether carboxylate-based solvent, or any combination thereof.

In particular, the solvent may include cyclopentanone, cyclohexanone, cycloheptanone, PGMEA, propylene glycol monoethyl ether acetate, propylene glycol monopropyl ether acetate, propylene glycol monobutyl ether acetate, or any combination thereof.

More particularly, the solvent may include PGMEA, propylene glycol monoethyl ether acetate, propylene glycol monopropyl ether acetate, propylene glycol monobutyl ether acetate, or any combination thereof.

In some example embodiments, the solvent may further include a nonpolar solvent. Specifically, the nonpolar solvent may include a hydrocarbon-based solvent.

Examples of the hydrocarbon-based solvent may include: an aliphatic hydrocarbon-based solvent such as n-pentane, isopentane, n-hexane, isohexane, n-heptane, isoheptane, 2,2,4-trimethylpentane, n-octane, isooctane, cyclohexane, or methylcyclohexane; and an aromatic hydrocarbon-based solvent such as benzene, toluene, xylene, mesitylene, ethylbenzene, trimethylbenzene, methylethylbenzene, n-propylbenzene, isopropylbenzene, diethylbenzene, isobutylbenzene, triethylbenzene, diisopropylbenzene, or n-amylnaphthalene.

The resist composition substantially may not include water or a polar protic organic solvent, and thus the solvent may not include water. For example, the resist composition may not include any or substantially water and/or may not include any or substantially a polar protic organic solvent. Specifically, the resist composition may include water at 1 wt % or less of a total weight of the resist composition and/or a polar protic organic solvent at 1 wt % or less of the total weight of the resist composition, and the solvent may include water at 1 wt % or less of a total weight of the solvent and/or a polar protic organic solvent at 1 wt % or less of the total weight of the solvent.

The solvent may be included in a range of about 0 parts by weight to about 99.9 parts by weight with respect to 100 parts by weight of the resist composition. As the organic solvent, one type of an organic solvent may be used, or two or more different types of organic solvents may be mixed and used.

### Any Components

The resist composition may further include a surfactant, a crosslinking agent, a leveling agent, a colorant, or any combination thereof as necessary.

The resist composition may further include a surfactant to improve coatability, developability, and the like. A specific example of the surfactant may include, for example, a nonionic surfactant such as polyoxyethylene lauryl ether, polyoxyethylene stearyl ether, polyoxyethylene oleyl ether, polyoxyethylene n-octylphenyl ether, polyoxyethylene n-nonylphenyl ether, polyethylene glycol dilaurate, or polyethylene glycol distearate. As the surfactant, a commercially available product or a synthetic product may be used. Examples of the commercially available product of the surfactant may include KP341 (manufactured by Shin-Etsu Chemical Co., Ltd.), Polyflow No. 75 and Polyflow No. 95 (manufactured by Kyoeisha Chemical Co., LTD.), Eftop EF301, Eftop 303, and Eftop 352 (manufactured by Mitsubishi Materials Electronic Chemicals Co., Ltd.), MEGAFACE™ F171, MEGAFACE™ F173, R-40, R-41, and R-43 (products manufactured by DIC Corporation), Fluorad™ FC430 and Fluorad™ FC431 (manufactured by Sumitomo 3M, Ltd.), Asahi Guard™ AG710 (manufactured by AGC Seimi Chemical Co., Ltd.), and Surflon™ S-382, Surflon™ SC-101, Surflon™ SC-102, Surflon™ SC-103, Surflon™ SC-104, Surflon™ SC-105, and Surflon™ SC-106 (manufactured by AGC Seimi Chemical Co., Ltd.).

The surfactant may be included in a range of about 0 parts by weight to about 20 parts by weight with respect to 100 parts by weight of the resist composition. As the surfactant, one type of a surfactant may be used, or two or more different types of surfactants may be mixed and used.

A method of preparing the resist composition is not particularly limited, and for example, a method of mixing a polymer and any components added as needed in an organic solvent may be used. A temperature or time during mixing is not particularly limited. If necessary, filtration may be performed after mixing.

### [Method of Forming Pattern]

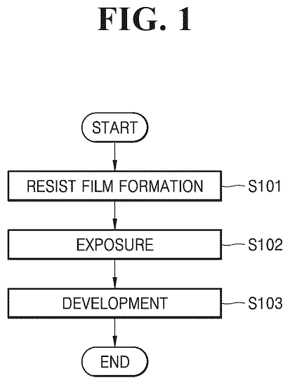

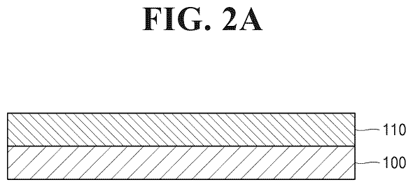

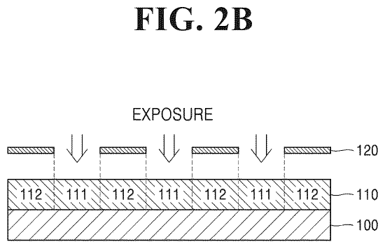

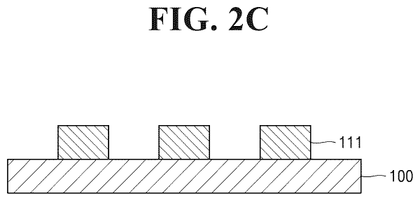

Hereinafter, a method of forming a pattern according to some example embodiments will be described in more detail with reference to FIGS. 1 and 2A to 2C. FIG. 1 is a flowchart illustrating the method of forming a pattern according to some example embodiments, and FIGS. 2A to 2C are side cross-sectional views illustrating the method of forming a pattern according to some example embodiments. Hereinafter, an example of the method of forming a pattern using a negative resist composition will be described in detail, but one or more embodiments are not limited thereto.

Referring to FIG. 1, the method of forming a pattern may include operation S101 of applying a resist composition to form a resist film, operation S102 of exposing at least a portion of the resist film to high-energy rays to form an exposed resist film, and operation S103 of developing the exposed resist film based on using a developer. Such operations may be omitted if necessary or may be performed in a different order.

First, referring to FIG. 1 and FIG. 2A, a substrate 100 may be prepared. The substrate 100 may include, for example, a semiconductor substrate such as a silicon substrate or a germanium substrate, glass, quartz, ceramic, or copper. In some example embodiments, the substrate 100 may include a Group III-V compound such as GaP, GaAs, or GaSb.

The resist composition may be applied to a desired thickness onto the substrate 100, specifically, through a coating method, to form a resist film 110. The applied resist composition may be the resist composition as described herein according to any of the example embodiments. Accordingly, the resist film 110 may include the resist composition according to any of the example embodiments. If necessary, post application bake (PAB) may be performed to remove an organic solvent remaining in the resist film 110. In some example embodiments, the resist film 110 may be heated to generate radicals, and then the radicals may be chemically bonded through exposure to form a crosslink.

As the coating method, spin coating, dipping, roller coating, or other general coating methods may be used. Among the coating methods, in particular, spin coating may be used, and the viscosity, concentration, and/or spin speed of the resist composition may be adjusted to form the resist film 110 having a desired thickness. Specifically, the resist film 110 may have a thickness of about 10 nm to about 300 nm. More specifically, the resist film 110 may have a thickness of about 30 nm to about 200 nm.

A lower limit of a temperature of the PAB may be 60° C. or more, specifically, 80° C. or more. In addition, an upper limit of the temperature of the PAB may be 150° C. or less, specifically, 140° C. or less. A lower limit of a time of the PAB may be 5 seconds or more, specifically, 10 seconds or more. An upper limit of the time of the PAB may be 600 seconds or less, specifically, 300 seconds or less.

Before the resist composition is applied onto the substrate 100, an etching target film (not shown) may be further formed on the substrate 100. The etching target film may refer to a layer on which an image is transferred from a resist pattern and converted into a certain pattern. In some example embodiments, the etching target film may be formed to include, for example, an insulating material such as silicon oxide, silicon nitride, or silicon oxynitride. In some example embodiments, the etching target film may be formed to include a conductive material such as a metal, a metal nitride, a metal silicide, or a metal silicide nitride. In some example embodiments, the etching target film may be formed to include a semiconductor material such as polysilicon.

In some example embodiments, an antireflection film may be further formed on the substrate 100 to increase or maximize the efficiency of a resist. The antireflection film may be an organic or inorganic antireflection film.

In some example embodiments, a protective film may be further provided on the resist film 110 to reduce the influence of alkaline impurities or the like included during a process. In addition, when immersion exposure is performed, for example, a protective film for immersion may also be provided on the resist film 110 to avoid direct contact between an immersion medium and the resist film 110.

Next, referring to FIG. 1 and FIG. 2B, at least a portion of the resist film 110 may be exposed to high-energy rays, thereby establishing an exposed resist film. For example, high-energy rays passing through a mask 120 may be irradiated onto at least a portion of the resist film 110. Thus, based on the exposing, the resist film 110 (e.g., the exposed resist film) may have an exposed portion 111 and an unexposed portion 112.

Although not limited to a specific theory, radicals may be generated in the exposed portion 111 through exposure, and chemical bonds may be formed between the radicals so that the physical properties of the resist composition may be changed.

In some cases, the exposure may be performed by (e.g., based on) irradiating high-energy rays through a mask 120 with a certain pattern by using a liquid such as water as a medium. Examples of the high-energy rays may include electromagnetic waves such as UV rays, deep ultraviolet (DUV) rays, extreme ultraviolet (EUV) rays (with a wavelength of 13.5 nm), X-rays, and y-rays; and charged particle beams such as electron beams (EBs) and a rays. Irradiating the high-energy rays may be collectively referred to as “exposure.”

Examples of an exposure light source may include various light sources such as a light source that emits laser light in a UV region, such as a KrF excimer laser (with a wavelength of 248 nm), an ArF excimer laser (with a wavelength of 193 nm), or an F2 excimer laser (with a wavelength of 157 nm), a light source that converts a wavelength of laser light from a solid-state laser light source (yttrium aluminum garnet (YAG) or semiconductor laser or the like) to emit harmonic laser light in a far UV or vacuum UV region, and a light source that irradiates EBs or EUV rays. During exposure, the exposure may be usually performed through a mask corresponding to a desired pattern, but when exposure light is an EB, the exposure may be performed through direct writing without using a mask.

Regarding an integral dose of high-energy rays, for example, when EUV rays are used as the high-energy rays, the integral dose may be 2,000 mJ/cm² or less, specifically, 500 mJ/cm² or less. In addition, when EBs are used as the high-energy rays, the integral dose may be 5,000 μC/cm² or less, specifically, 1,000 μC/cm² or less.

In addition, post-exposure bake (PEB) may be performed after the exposure. A lower limit of a temperature of the PEB may be 50° C. or more, specifically, 80° C. or more. An upper limit of the temperature of the PEB may be 250° C. or less, specifically, 200° C. or less. A lower limit of a time of the PEB may be 5 seconds or more, specifically, 10 seconds or more. An upper limit of the time of the PEB may be 600 seconds or less, specifically, 300 seconds or less.

Next, referring to FIG. 1 and FIG. 20, the exposed resist film 110 may be developed by using a developer. The unexposed portion 112 may be washed away and removed by the developer, and the exposed portion 111 of the exposed resist film 110 may remain without being washed away by the developer. The resultant structure as shown in FIG. 2C may be a resist pattern.

Examples of the developer may include an alkaline developer and a developer including an organic solvent (hereinafter also referred to as “organic developer”). Examples of a developing method may include a dipping method, a puddle method, a spray method, a dynamic injection method, and the like. A developing temperature may be, for example, in a range of about 5° C. to about 60° C., and a developing time may be, for example, in a range of about 5 seconds to about 300 seconds.

The alkaline developer may include, for example, an alkaline aqueous solution in which one or more alkaline compounds such as sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethyamine, ethyldimethylamine, triethanolamine, tetramethyl ammonium hydroxide (TMAH), pyrrole, piperidine, choline, 1,8-diazabicyclo[5.4.0]-7-undecene (DBU), and 1,5-diazabicyclo[4.3.0]-5-nonene (DBN) are dissolved. The alkaline developer may further include a surfactant.

A lower limit of a content of the alkaline compound in the alkali developer may be 0.1 wt % or more, specifically, 0.5 wt % or more, and more specifically, 1 wt % or more. In addition, an upper limit of the content of the alkaline compound in the alkaline developer may be 20 wt % or less, specifically, 10 wt % or less, and more specifically, 5 wt % or less.

Examples of the organic solvent included in the organic developer may include the same organic solvent as those exemplified in the part of <Solvent> of [Resist composition]. Alternatively, as the organic solvent, an alcohol-based solvent, a lactate-based solvent, a hydrocarbon-based solvent, or the like may be used.

Examples of the alcohol-based solvent may include: a monoalcohol-based solvent such as methanol, ethanol, n-propanol, isopropanol (IPA), 1-methoxy-2-propanol, 1-ethoxy-2-propanol, n-butanol, isobutanol, sec-butanol, tert-butanol, n-pentanol, isopentanol, 2-methylbutanol, sec-pentanol, tert-pentanol, 3-methoxybutanol, 3-methyl-3-methoxybutanol, n-hexanol, 2-methylpentanol, sec-hexanol, 2-ethylbutanol, 4-methyl-2-pentanol (MIBC), sec-heptanol, 3-heptanol, n-octanol, 2-ethylhexanol, sec-octanol, n-nonylalcohol, 2,6-dimethyl-4-heptanol, n-decanol, sec-undecyl alcohol, trimethylnonyl alcohol, sec-tetradecyl alcohol, sec-heptadecyl alcohol, furfuryl alcohol, phenol, cyclohexanol, methylcyclohexanol, 3,3,5-trimethylcyclohexanol, benzyl alcohol, or diacetone alcohol; a polyhydric alcohol-based solvent such as ethylene glycol, 1,2-propylene glycol, 1,3-butylene glycol, 2,4-pentanediol, 2-methyl-2,4-pentanediol, 2,5-hexanediol, 2,4-heptanediol, 2-ethyl-1,3-hexanediol, diethylene glycol, dipropylene glycol, triethylene glycol, or tripropylene glycol; and a polyhydric alcohol-containing ether-based solvent such as ethylene glycol monomethyl ether, ethylene glycol monoethyl ether, ethylene glycol monopropyl ether, ethylene glycol monobutyl ether, ethylene glycol monohexyl ether, ethylene glycol monophenyl ether, ethylene glycol mono-2-ethylbutyl ether, diethylene glycol monomethyl ether, diethylene glycol monoethyl ether, diethylene glycol monopropyl ether, diethylene glycol monobutyl ether, diethylene glycol monohexyl ether, propylene glycol monomethyl ether (PGME), propylene glycol monoethyl ether, propylene glycol monopropyl ether, propylene glycol monobutyl ether, dipropylene glycol monomethyl ether, dipropylene glycol monoethyl ether, or dipropylene glycol monopropyl ether.

Examples of the lactate-based solvent may include methyl lactate, ethyl lactate, n-butyl lactate, n-amyl lactate, and the like.

Specifically, n-butyl acetate (nBA), PGME, PGMEA, ethyl lactate (EL), GBL, IPA, or the like may be used as the organic developer. The organic developer may further include an organic acid such as an acetic acid, a formic acid, or a citric acid.

A lower limit of a content of the organic solvent in the organic developing solvent may be 80 wt % or more, specifically, 90 wt % or more, more specifically, 95 wt % or more, or particularly, 99 wt % or more.

The organic developing solvent may also include a surfactant. In addition, a trace amount of water may be included in the organic developing solvent. Furthermore, during developing, the developing may be stopped by substituting the organic developer with a solvent that is a different type therefrom.

The resist pattern after the developing may be further cleaned. Ultrapure water, a rinse solution, or the like may be used as a cleaning solution. A rinse solution is not particularly limited as long as the rinse solution does not dissolve a resist pattern, and a solution including a general organic solvent may be used. For example, the rinse solution may be an alcohol-based solvent or an ester-based solvent. After the cleaning, the rinse solution remaining on the substrate 100 and the resist pattern may be removed. In addition, when ultrapure water is used, water remaining on the substrate 100 and the resist pattern may be removed.

In addition, developers may be used singly or in a combination of two or more.

After the resist pattern is formed as described above, a pattern interconnection substrate may be obtained through etching. The etching may be performed through a known method including dry etching using a plasma gas and wet etching using an alkaline solution, a copper (II) chloride solution, an iron (II) chloride solution, or the like.

After the resist pattern is formed, plating may be performed. The plating is not particularly limited, and examples thereof may include copper plating, solder plating, nickel plating, gold plating, and the like.

The resist pattern remaining after the etching may be peeled off with an organic solvent. One or more embodiments are not limited thereto, but examples of such an organic solvent may include PGMEA, PGME, EL, and the like. A peeling method is not particularly limited, but examples thereof may include an immersion method, a spray method, and the like. In addition, the pattern interconnection substrate on which the resist pattern is formed may be a multi-layer interconnection substrate or may have small-diameter through-holes.

In some example embodiments, the pattern interconnection substrate may be formed through a method of forming a resist pattern, depositing a metal in a vacuum, and then melting the resist pattern with a solution, that is, a lift-off method.

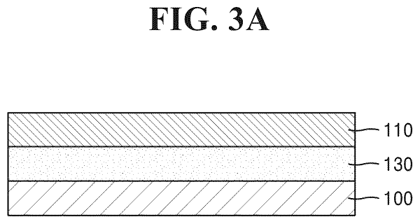

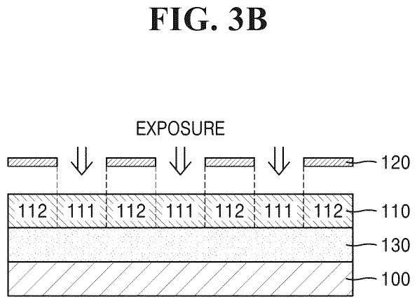

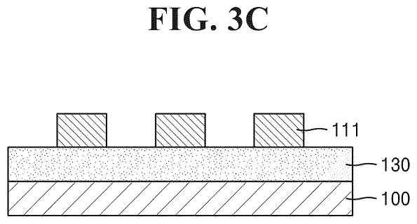

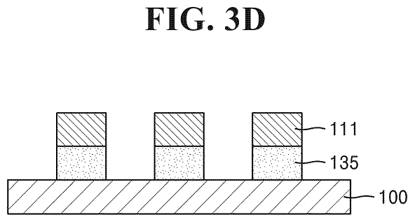

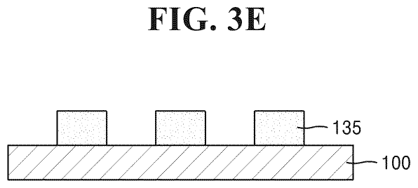

FIGS. 3A, 3B, 3C, 3D, and 3E are cross-sectional side views illustrating a method of forming a patterning structure, according to some example embodiments.

As shown in FIG. 3A, before a resist film 110 is formed on a substrate 100, a material layer 130 may be formed on the substrate 100. The resist film 110 may be formed on the material layer 130. The material layer 130 may include an insulating material (for example, silicon oxide or silicon nitride), a semiconductor material (for example, silicon), or a metal (for example, copper). In some example embodiments, the material layer 130 may have a multi-layer structure. A material of the material layer 130 may be different from a material of the substrate 100.

As shown in FIG. 3B, the resist film 110 may be subjected to a pre-exposure bake process and exposed to high-energy light (e.g., high-energy rays) through a mask 120, and then the resist film 110 may include an exposed portion 111 and an unexposed portion 112.

As shown in FIG. 3C, the exposed resist film 110 may be developed by using a developer (for example, a developing agency). The unexposed portion 112 may be washed away by the developer, and the exposed portion 111 of the exposed resist film 110 may remain without being washed away by the developer.

As shown in FIG. 3D, an exposed portion of the material layer 130 may be etched by using the resist film 110 as a mask to form a material pattern 135 on the substrate 100. As shown in FIG. 3E, the resist film 110 may be removed.

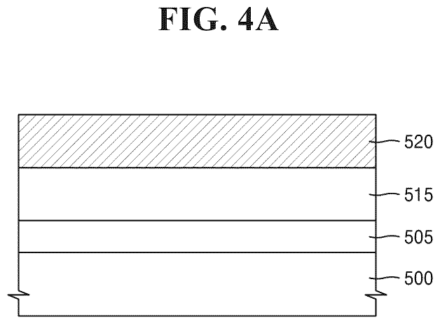

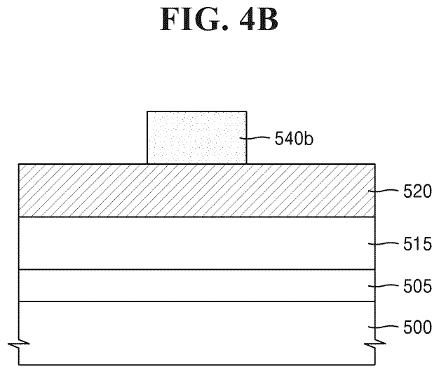

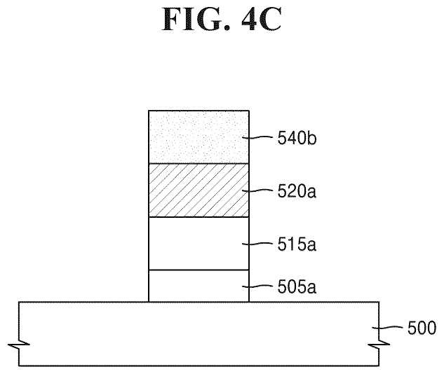

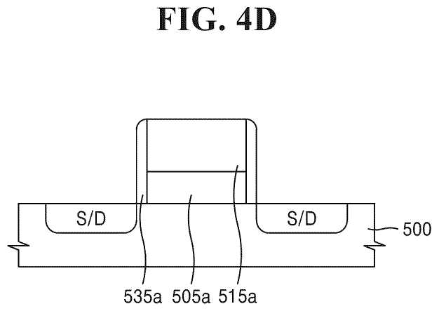

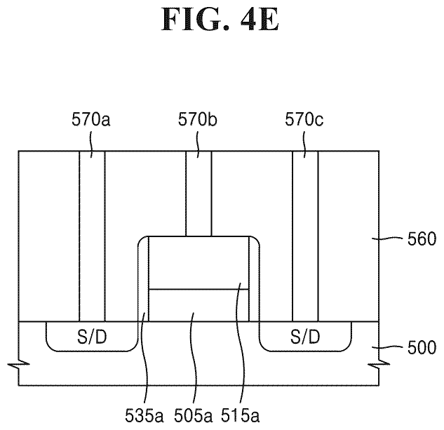

FIGS. 4A, 4B, 4C, 4D, and 4E are side cross-sectional views illustrating a method of forming a semiconductor device according to some example embodiments.

As shown in FIG. 4A, a gate dielectric 505 (for example, silicon oxide) may be formed on a substrate 500. The substrate 500 may be a semiconductor substrate such as a silicon substrate. A gate layer 515 (for example, doped polysilicon) may be formed on the gate dielectric 505. A hardmask layer 520 may be formed on the gate layer 515.

As shown in FIG. 4B, a resist pattern 540b may be formed on the hardmask layer 520. The resist pattern 540b may be formed by using a resist composition according to some example embodiments. The resist composition may include an organic solvent.

As shown in FIG. 4C, the gate layer 515 and the gate dielectric 505 may be etched to form a hardmask pattern 520a, a gate electrode pattern 515a, and a gate dielectric pattern 505a.

As shown in FIG. 4D, a spacer layer may be formed on the gate electrode pattern 515a and the gate dielectric pattern 505a. The spacer layer may be formed by using a deposition process (for example, chemical vapor deposition (CVD)). The spacer layer may be etched to form a spacer 535a (for example, silicon nitride) on sidewalls of the gate electrode pattern 515a and the gate dielectric pattern 505a. After the spacer 535a is formed, ions may be implanted into the substrate 500 to form source/drain impurity regions S/D.

As shown in FIG. 4E, an interlayer insulating film 560 (for example, oxide) may be formed on the substrate 500 to cover the gate electrode pattern 515a, the gate dielectric pattern 505a, and the spacer 535a. Thereafter, electrical contacts 570a, 570b, and 570c connected to the gate electrode pattern 515a and the source/drain impurity regions S/D may be formed in the interlayer insulating film 560. The electrical contacts 570a, 570b, and 570c may be formed of a conductive material (for example, metal). Although not shown, a barrier layer may be formed between a sidewall of the interlayer insulating film 560 and the electrical contacts 570a, 570b, and 570c.

FIGS. 4A to 4E illustrate an example in which a transistor is formed, but the inventive concepts are not limited thereto.

The resist composition according to some example embodiments may be used in a patterning process of forming other types of semiconductor apparatuses.

The inventive concepts will be described in more detail using the following Examples and Comparative Examples, but the technical scope of the inventive concepts is not limited only to the following Examples.

### EXAMPLES

### Synthesis Example 1: Synthesis of Sb-1

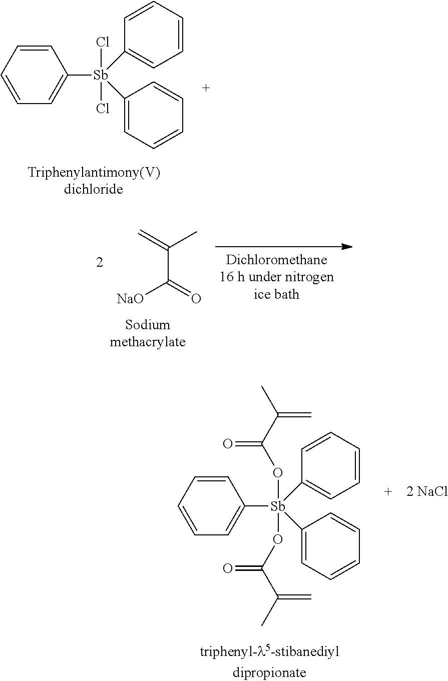

Triphenyl antimony (V) dichloride (12 mmol) was dissolved in 113 mL of dichloromethane and cooled in an ice bath. After sodium methacrylate (29 mmol) was further added, a mixture was stirred in an ice bath for 16 hours. After a reaction was terminated, NaCl and unreacted sodium metacrylate were removed by using a paper filter and a syringe filter (0.1 μm), and a residual solvent was distilled off and dried in a 60 degree vacuum oven for 12 hours to obtain 5.3 g of triphenyl-λ⁵-stibanediyl dipropionate (Sb-1) (yield 86%). The obtained Sb-1 was confirmed with ¹H-NMR.

¹H-NMR (500 MHZ, MC-d₆): δ 8.020, 8.009 (aromatic ortho-), 7.537 (aromatic meta-, para-), 5.960, 5.414 (methylene), 5.344 (MC-d), 1.810 (methyl)

### Synthesis Example 2: Synthesis of Sb-2

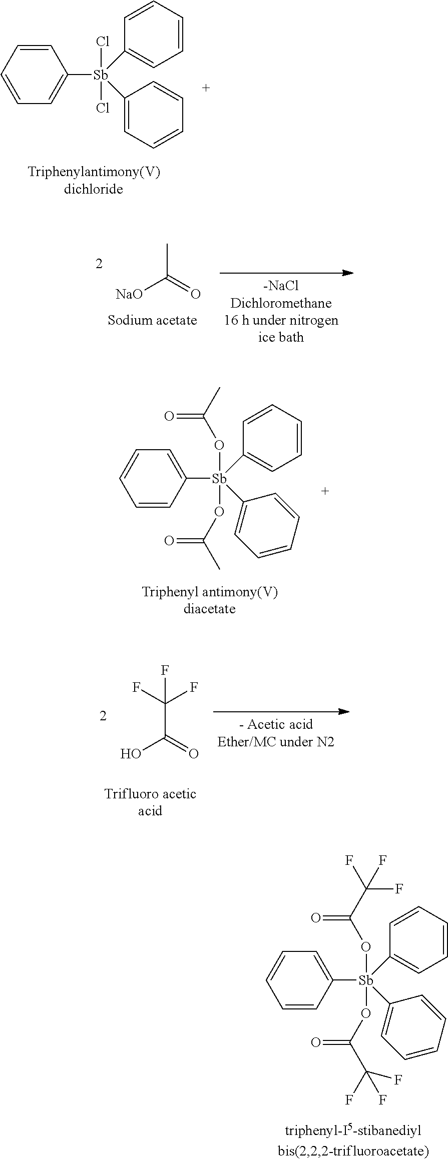

Triphenyl antimony (V) dichloride (12 mmol) was dissolved in 225 ml of dichloromethane and cooled in an ice bath. After sodium acetate (29 mmol) was further added, a mixture was stirred in an ice bath for 16 hours. After a reaction was terminated, NaCl was removed by using a paper filter and a syringe filter (0.1 μm), and a residual solvent was distilled off and dried in a 60 degree vacuum oven for 12 hours to obtain 4.6 g of triphenyl antimony (V) diacetate.

Next, 2 g of triphenyl antimony (V) diacetate and 1.34 g of a trifluoro acetic acid were added to 90 ml of ethyl acetate/dichloromethane (v:v of 1:1) and stirred for 16 hours under nitrogen purge. After a reaction was terminated, a residual solvent was distilled off and dried in a 60 degree vacuum oven for 12 hours to obtain 2.03 g of triphenyl->5-stibanediyl bis(2,2,2-trifluoroacetate (Sb-2) (yield 74%). The obtained Sb-2 was confirmed with ¹H-NMR.

¹H-NMR (500 MHZ, DMSO-d₆): δ 8.002, 7.989 ppm (aromatic ortho-), 7.688 (aromatic meta-, para-), 5.344 (MC-d)

### Synthesis Example 3: Synthesis of Sb-3

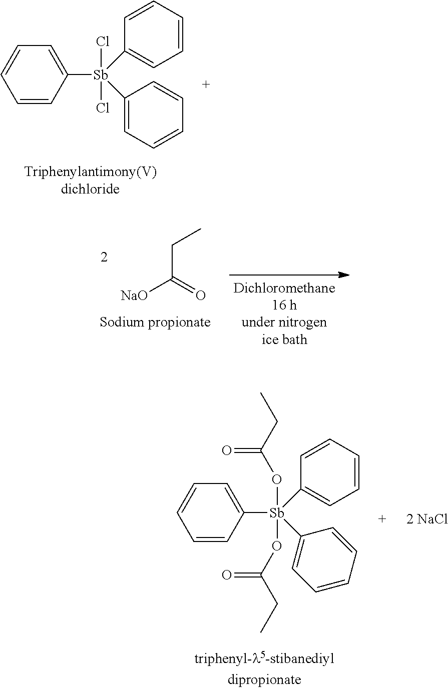

5.0 g of triphenyl-λ⁵-stibanediyl dipropionate (Sb-3) (yield 85%) was synthesized in the same manner as in Synthetic Example 1, except that sodium propionate (12 mmol) was used instead of sodium methacrylate (12 mmol). The obtained Sb-3 was confirmed with ¹H-NMR.

¹H-NMR (500 MHZ, DMSO-d₆): δ 7.985, 7.974 (aromatic ortho-), 7.544 (aromatic meta-, para-), 5.344 (MC-d), 2.149, 2.134 (tetra, -methylene), 0.941 (triplet,-methyl)

### Preparation Example: Preparation of Resist Composition

Organometallic compounds synthesized in Synthetic Examples 1 to 3 were respectively dissolved at 2 wt % in solvents shown in Table 1 below. Next, immediately after such solutions were obtained, the solutions were stored in an oven at a temperature of 40° C. for 1 week, 2 weeks, and 3 weeks, respectively, thereby obtaining compositions A-1 to A-4, B-1 to B-4, C-1 to C-4, D-1 to D-4, E-1 to E-4, and F-1 to F-4.

TABLE 1

| Casting | Organometallic | pKa of | | Storage in |
|---|---|---|---|---|
| solution No. | compound | ligand | Solvent | oven at 40° C. |
| A-1 | Sb-1 | 4.475 | PGMEA | None |
| A-2 | Sb-1 | 4.475 | PGMEA | 1 week |
| A-3 | Sb-1 | 4.475 | PGMEA | 2 weeks |
| A-4 | Sb-1 | 4.475 | PGMEA | 3 weeks |
| B-1 | Sb-1 | 4.475 | EL | None |
| B-2 | Sb-1 | 4.475 | EL | 1 week |
| B-3 | Sb-1 | 4.475 | EL | 2 weeks |
| B-4 | Sb-1 | 4.475 | EL | 3 weeks |
| C-1 | Sb-2 | −0.387 | PGMEA | None |
| C-2 | Sb-2 | −0.387 | PGMEA | 1 week |
| C-3 | Sb-2 | −0.387 | PGMEA | 2 weeks |
| C-4 | Sb-2 | −0.387 | PGMEA | 3 weeks |
| D-1 | Sb-2 | −0.387 | EL | None |
| D-2 | Sb-2 | −0.387 | EL | 1 week |
| D-3 | Sb-2 | −0.387 | EL | 2 weeks |
| D-4 | Sb-2 | −0.387 | EL | 3 weeks |
| E-1 | Sb-3 | 4.759 | PGMEA | None |
| E-2 | Sb-3 | 4.759 | PGMEA | 1 week |
| E-3 | Sb-3 | 4.759 | PGMEA | 2 weeks |
| E-4 | Sb-3 | 4.759 | PGMEA | 3 weeks |
| F-1 | Sb-3 | 4.759 | EL | None |
| F-2 | Sb-3 | 4.759 | EL | 1 week |
| F-3 | Sb-3 | 4.759 | EL | 2 weeks |
| F-4 | Sb-3 | 4.759 | EL | 3 weeks |

### Evaluation Example 1: Evaluation of Thermal Stability

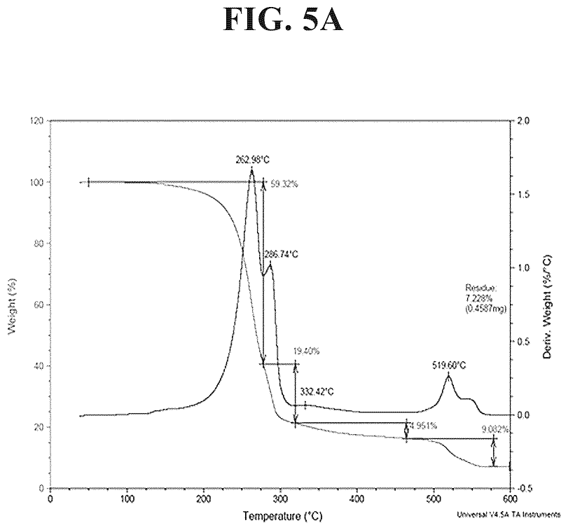

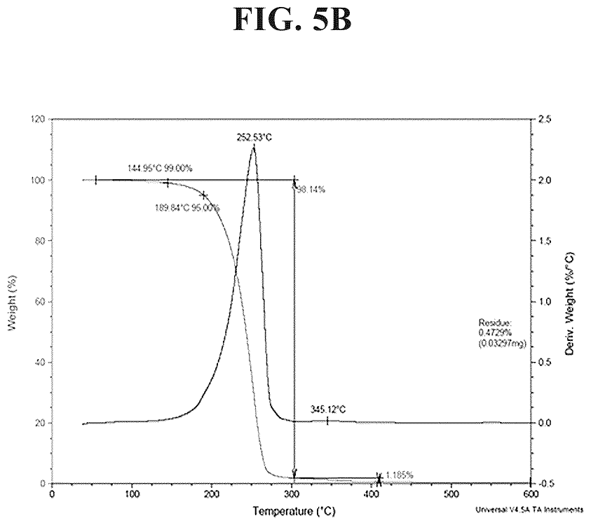

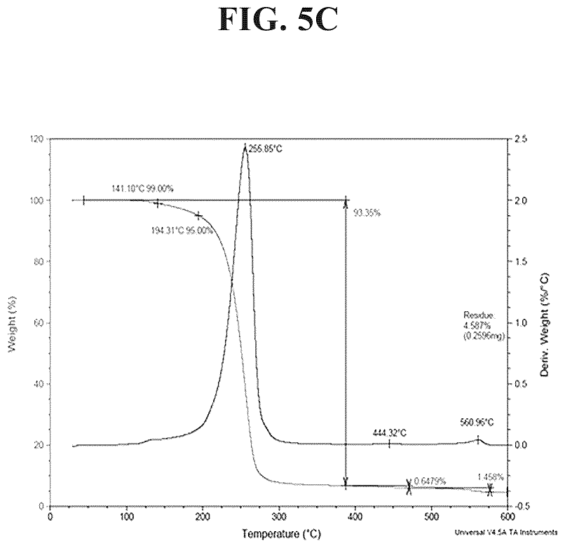

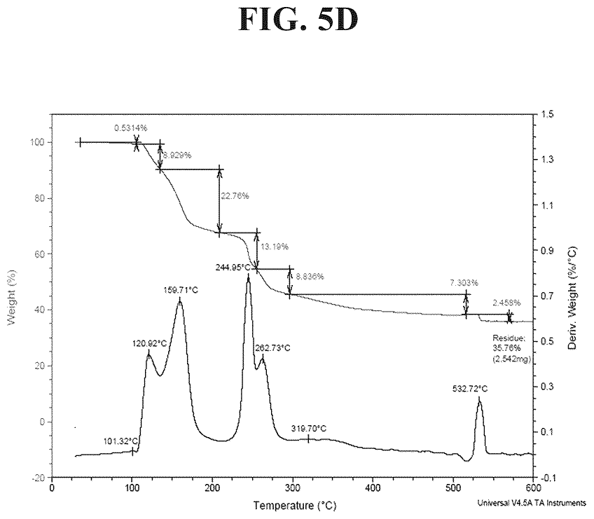

The organometallic compounds obtained in Synthetic Examples 1 to 3 and the following M-01 were subjected to thermal analysis using thermogravimetric analysis (TGA) and differential scanning calorimetry (DSC) (N₂ atmosphere, temperature range: from room temperature to 600° C. (10° C./min)−TGA, from room temperature to 200° C. (10° C./min)−DSC, pan type: Pt pan in disposable Al pan (TGA), disposable Al pan (DSC)). Results thereof are shown in Table 2 and FIGS. 5A to 5D. During TGA analysis, a temperature of a point at which a mass of a sample becomes 99% of an initial mass is denoted by T_{d} (1%), and a temperature of a point at which the mass of the sample becomes 95% of the initial mass is denoted by T_{d} (5%). In Table 2, T_{g} (C) is the glass transition temperature of each respective compound.

TABLE 2

| Compound No. | T_{d} (5 %, ° C.) | T_{g} (° C.) | Graph |
|---|---|---|---|
| Sb-1 | 211 | 159 | FIG. 5A |
| Sb-2 | 190 | N/A | FIG. 5B |
| Sb-3 | 194 | 138 | FIG. 5C |
| M-01 | 123 | N/A | FIG. 5D |

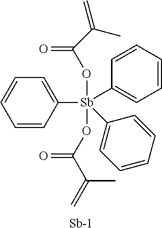

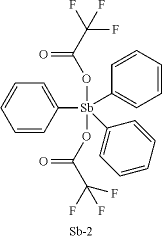

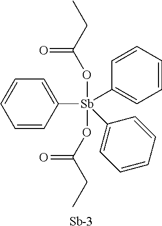

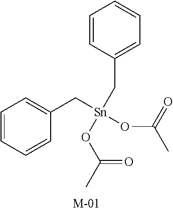

Referring to Table 2 above, it was confirmed that Sb-1 to Sb-3 were all stable to the extent that thermal decomposition did not substantially occur during a heat treatment process for pattern formation. On the other hand, it was confirmed that M-01 had relatively low thermal stability.

### Evaluation Example 2: Evaluation of Solid-State Storage Stability

The organometallic compound Sb-1 obtained in Synthetic Example 1 was stored in a solid state at room temperature for 20 days with exclusion of light and then confirmed with ¹H-NMR.

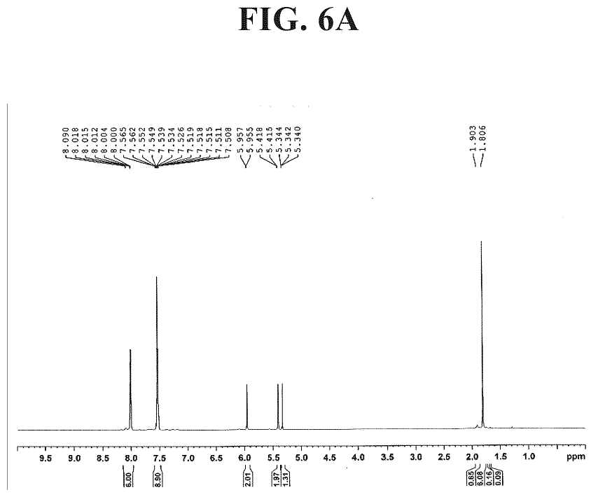

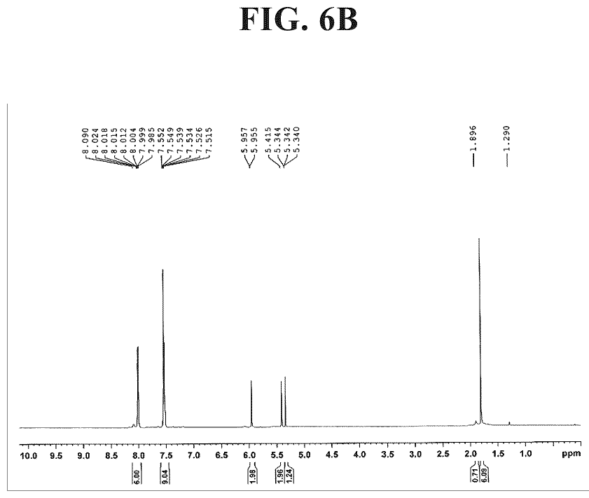

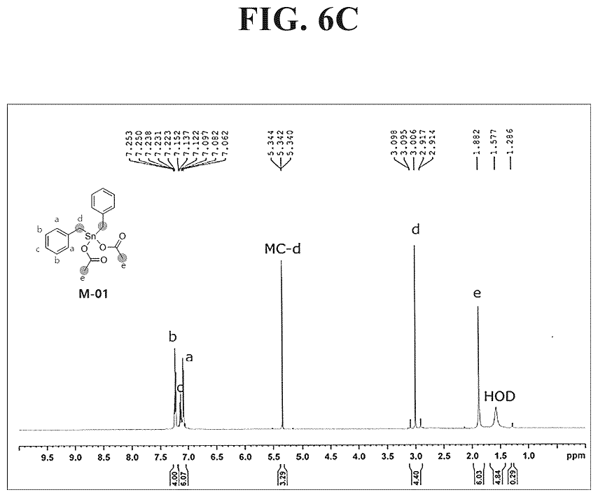

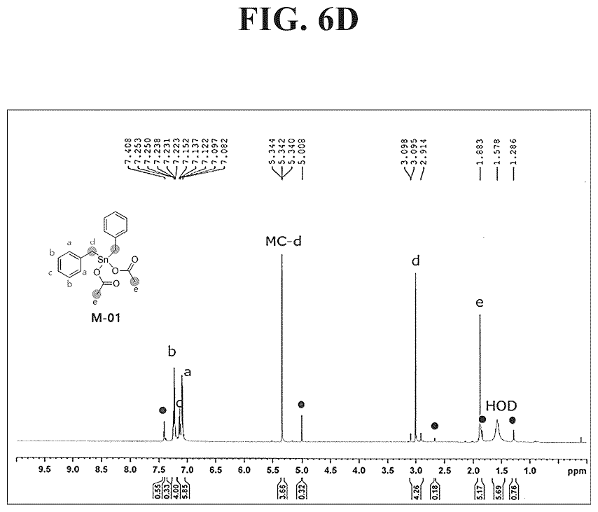

FIG. 6A is a diagram illustrating ¹H-NMR data of Sb-1 immediately after synthesis, and FIG. 6B is a diagram illustrating ¹H-NMR data of Sb-1 after storage in a solid state at room temperature for 20 days. As a result, it was confirmed that the ¹H-NMR data immediately after synthesis and the ¹H-NMR data after storage for 20 days were substantially the same. From the result, it was confirmed that the organometallic compound of the inventive concepts had high solid-state storage stability to the extent that the organometallic compound did not need to be stored in a low-temperature nitrogen cabinet.

On the other hand, when M-01 was stored in a solid state at room temperature for 20 days with exclusion of light and then confirmed with ¹H-NMR. As a result, it was confirmed that, after storage for 20 days, Sn—O and Sn—C bonds were each decomposed by 14% in ¹H-NMR data. FIG. 60 is a diagram illustrating ¹H-NMR data of M-01 immediately after synthesis, and FIG. 6D is a diagram illustrating ¹H-NMR data of M-01 after storage in a solid state at room temperature for 20 days.

### Evaluation Example 3: Evaluation of Liquid-State Storage Stability

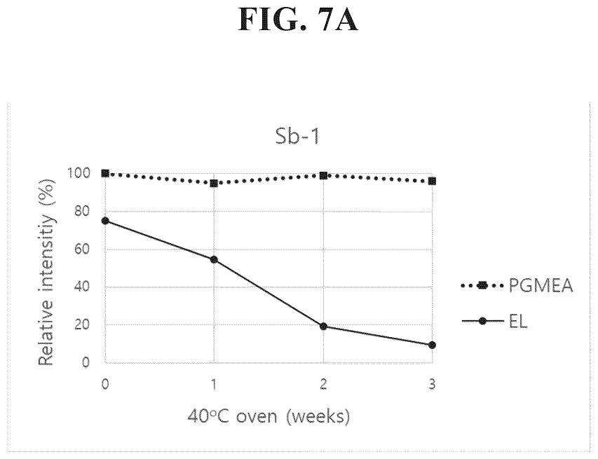

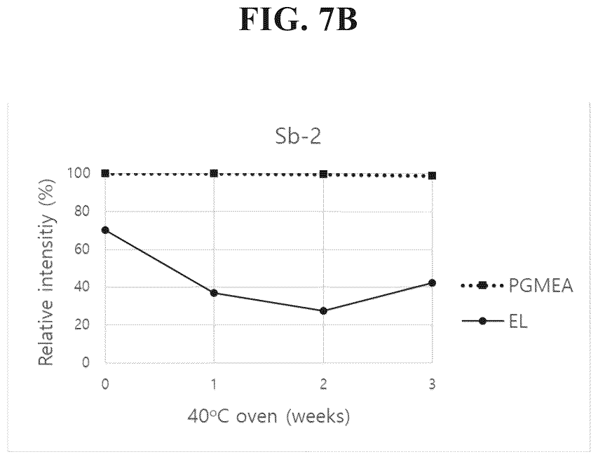

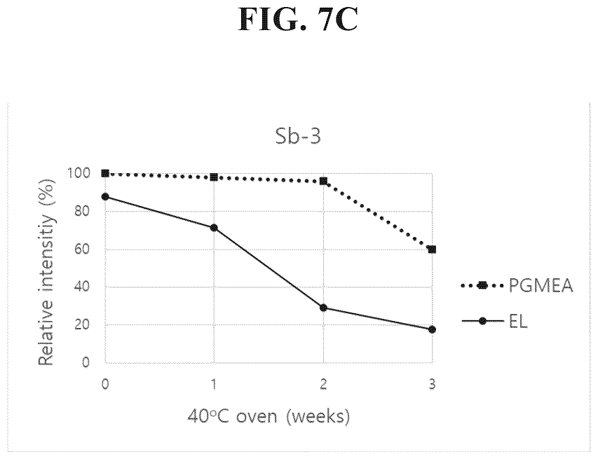

For compositions A-1 to A-4, B-1 to B-4, C-1 to C-4, D-1 to D-4, E-1 to E-4, and F-1 to F-4, the relative intensities of GPC spectra measured at a wavelength of 264 nm by using GPC (Waters alliance, e2695 system) were measured and recorded in Table 3 below and shown in FIGS. 7A to 7C. For a PGMEA solution including M-01 and an EL solution including M-01, the liquid-state storage stability was also evaluated by measuring the relative intensities of GPC spectra measured at a wavelength of 264 nm, respectively. However, it was confirmed that, after storage for 1 week, the relative intensity was substantially converged to 0 and was at an unmeasurable level.

TABLE 3

| | | | | | Storage in | | GPC spectrum |
|---|---|---|---|---|---|---|---|
| | Composition | Organometallic | pKa of | | oven at | | relative |
| Example No. | No. | compound | ligand | Solvent | 40° C. | | intensity (%) |
| Example 1-1 | A-1 | Sb-1 | 4.475 | PGMEA | None | | 100 |
| Example 1-2 | A-2 | Sb-1 | 4.475 | PGMEA | 1 | week | 94.9 |
| Example 1-3 | A-3 | Sb-1 | 4.475 | PGMEA | 2 | weeks | 99.0 |
| Example 1-4 | A-4 | Sb-1 | 4.475 | PGMEA | 3 | weeks | 95.8 |
| Comparative | B-1 | Sb-1 | 4.475 | EL | None | | 74.9 |
| Example 1-1 | | | | | | | |
| Comparative | B-2 | Sb-1 | 4.475 | EL | 1 | week | 54.4 |
| Example 1-2 | | | | | | | |
| Comparative | B-3 | Sb-1 | 4.475 | EL | 2 | weeks | 19.3 |
| Example 1-3 | | | | | | | |
| Comparative | B-4 | Sb-1 | 4.475 | EL | 3 | weeks | 9.5 |
| Example 1-4 | | | | | | | |
| Example 2-1 | C-1 | Sb-2 | −0.387 | PGMEA | None | | 100 |
| Example 2-2 | C-2 | Sb-2 | −0.387 | PGMEA | 1 | week | 100 |
| Example 2-3 | C-3 | Sb-2 | −0.387 | PGMEA | 2 | weeks | 99.6 |
| Example 2-4 | C-4 | Sb-2 | −0.387 | PGMEA | 3 | weeks | 98.8 |
| Comparative | D-1 | Sb-2 | −0.387 | EL | None | | 70.2 |
| Example 2-1 | | | | | | | |
| Comparative | D-2 | Sb-2 | −0.387 | EL | 1 | week | 37.0 |
| Example 2-2 | | | | | | | |
| Comparative | D-3 | Sb-2 | −0.387 | EL | 2 | weeks | 27.4 |
| Example 2-3 | | | | | | | |
| Comparative | D-4 | Sb-2 | −0.387 | EL | 3 | weeks | 42.2 |
| Example 2-4 | | | | | | | |
| Comparative | E-1 | Sb-3 | 4.759 | PGMEA | None | | 100 |
| Example 3-1 | | | | | | | |
| Comparative | E-2 | Sb-3 | 4.759 | PGMEA | 1 | week | 97.9 |
| Example 3-2 | | | | | | | |
| Comparative | E-3 | Sb-3 | 4.759 | PGMEA | 2 | weeks | 95.8 |
| Example 3-3 | | | | | | | |
| Comparative | E-4 | Sb-3 | 4.759 | PGMEA | 3 | weeks | 59.8 |
| Example 3-4 | | | | | | | |
| Comparative | F-1 | Sb-3 | 4.759 | EL | None | | 87.7 |
| Example 4-1 | | | | | | | |
| Comparative | F-2 | Sb-3 | 4.759 | EL | 1 | week | 71.2 |
| Example 4-2 | | | | | | | |
| Comparative | F-3 | Sb-3 | 4.759 | EL | 2 | weeks | 29.0 |
| Example 4-3 | | | | | | | |
| Comparative | F-4 | Sb-3 | 4.759 | EL | 3 | weeks | 17.7 |

Example 4-4

Referring to Table 3 above and FIGS. 7A to 7C, it was confirmed that, even when stored in an oven at a temperature of 40° C. for up to 3 weeks, Examples 1-1 to 1-4 and 2-1 to 2-4 showed a much reduced degree of deterioration as compared with Comparative Examples 3-1 to 3-4. From such a result, it was confirmed that the solution-phase storage stability could vary significantly according to a structure of a ligand of an organometallic compound.

In addition, it was confirmed that, even when stored in an oven at a temperature of 40° C. for up to 3 weeks, Examples 1-1 to 1-4 and 2-1 to 2-4 showed a much reduced degree of deterioration as compared with Comparative Examples 1-1 to 1-4 and 2-1 to 2-4. From such a result, it was confirmed that the solution-phase storage stability could vary significantly according to a type of a solvent included in a composition.

### Evaluation Example 4: Evaluation of Thin Film Phenomena

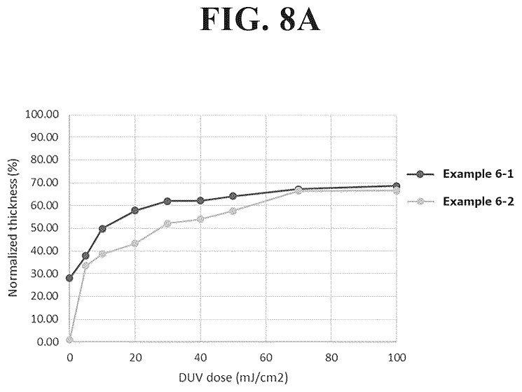

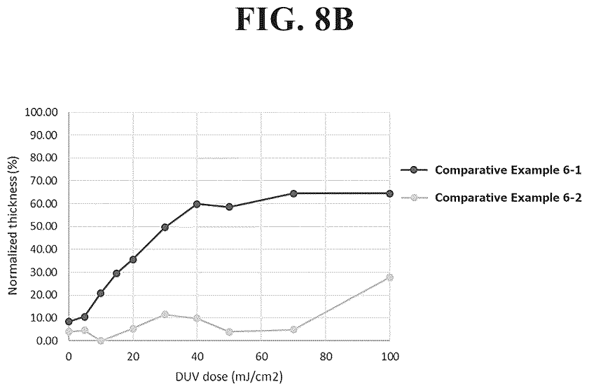

After a silicon wafer with a diameter of 8 inches was treated with O₂ plasma for 30 minutes, the silicon wafer was spin-coated with each of compositions A-1, A-4, B-1, and B-4 at a speed of 1,500 rpm for 1 minute and then PAB at a temperature of 120° C. for 1 minute to manufacture a film having a certain thickness. Then, after the film was cut into specimens having a size of 2 cm×2 cm, the film was exposed to DUV rays with a wavelength of 254 nm at a dose of 0 mJ/cm² to 100 mJ/cm² and PEB at a temperature of 120° C. for 1 minute. After the dried film was soaked in H₂O as a developer at a temperature 25° C. for 60 seconds, a residual solution was removed with an air gun and dried at a temperature of 120° C. for 1 minute to measure a thickness of the remaining film. Results of measurement are shown in FIGS. 8A and 8B.

TABLE 4

| | Casting | Organo- | | Storage | |
|---|---|---|---|---|---|
| | solution | metallic | | in oven | |
| | No. | compound | Solvent | at 40° C. | Graph |
| Example 6-1 | A-1 | Sb-1 | PGMEA | None | FIG. 8A |
| Example 6-2 | A-4 | Sb-1 | PGMEA | 3 weeks | FIG. 8A |
| Comparative | B-1 | Sb-1 | EL | None | FIG. 8B |
| Example 6-1 | | | | | |
| Comparative | B-4 | Sb-1 | EL | 3 weeks | FIG. 8B |
| Example 6-2 | | | | | |

Referring to FIGS. 8A and 8B, it was confirmed that in Example 6-1 and Example 6-2, the DUV contrast characteristics were similarly maintained, whereas in Comparative Example 6-1 and Comparative Example 6-2, the DUV contrast characteristics were lost after storage in an oven at a temperature of 40° C. for 3 weeks. That is, it was confirmed that a composition using EL was deteriorated after being stored in an oven at a temperature of 40° C. for 3 weeks and could no longer be used as a resist composition.

Some example embodiments may provide a resist composition having improved storage stability and improved sensitivity and providing a pattern with improved resolution, thereby enabling the formation of a semiconductor device having improved pattern resolutions, thereby enabling miniaturization of semiconductor devices with improved device reliability based on the reduced likelihood of device defects due to reduced likelihood of defects resulting from low pattern resolution.

It should be understood that example embodiments described herein should be considered in a descriptive sense only and not for purposes of limitation. Descriptions of features or aspects within each example embodiment should typically be considered as available for other similar features or aspects in other example embodiments. While some example embodiments have been described with reference to the drawings, it will be understood by those of ordinary skill in the art that various changes in form and details may be made therein without departing from the spirit and scope as defined by the following claims.

What is claimed is:

1. A resist composition, comprising:
an organometallic compound represented by Formula 1; and
a solvent including a polar aprotic solvent: 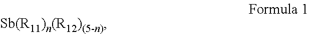
wherein, in Formula 1,
R₁₁ is a linear, branched, or cyclic monovalent C₁-C₃₀ hydrocarbon group having an acid dissociation constant (pKa) of 4.5 or less and optionally containing a heteroatom,
R₁₂ is a linear, branched, or cyclic C₁-C₃₀ monovalent hydrocarbon group optionally containing a heteroatom, and
n is an integer from 1 to 5.

2. The resist composition of claim 1, wherein, in Formula 1, R₁₁ has an acid dissociation constant (pKa) of 0 or less.

3. The resist composition of claim 1, wherein, in Formula 1,
R₁₁ is represented by *-(L₁₁)ₐ₁₁-X₁₁,
R₁₂ is represented by *-(L₁₂)ₐ₁₂-X₁₂,
L₁₁ is O, S, C═O, S═O, P═O, SO₂, PO₂, or PO₃,
L₁₂ is CRₐR_{b}, O, S, C—O, S—O, P═O, SO₂, PO₂, or PO₃,
a11 is an integer from 1 to 3,
a12 is an integer from 0 to 3,
X₁₁ and X₁₂ are each independently a substituted or unsubstituted C₁-C₃₀ alkyl group, a substituted or unsubstituted C₁-C₃₀ halogenated alkyl group, a substituted or unsubstituted C₁-C₃₀ alkoxy group, a substituted or unsubstituted C₁-C₃₀ alkylthio group, a substituted or unsubstituted C₁-C₃₀ halogenated alkoxy group, a substituted or unsubstituted C₁-C₃₀ halogenated alkylthio group, a substituted or unsubstituted C₃-C₃₀ cycloalkyl group, a substituted or unsubstituted C₃-C₃₀ cycloalkoxy group, a substituted or unsubstituted C₃-C₃₀ cycloalkylthio group, a substituted or unsubstituted C₃-C₃₀ heterocycloalkyl group, a substituted or unsubstituted C₃-C₃₀ heterocycloalkoxy group, a substituted or unsubstituted C₃-C₃₀ heterocycloalkylthio group, a substituted or unsubstituted C₂-C₃₀ alkenyl group, a substituted or unsubstituted C₂-C₃₀ alkenyloxy group, a substituted or unsubstituted C₂-C₃₀ alkenylthio group, a substituted or unsubstituted C₃-C₃₀ cycloalkenyl group, a substituted or unsubstituted C₃-C₃₀ cycloalkenyloxy group, a substituted or unsubstituted C₃-C₃₀ cycloalkenylthio group, a substituted or unsubstituted C₃-C₃₀ heterocycloalkenyl group, a substituted or unsubstituted C₃-C₃₀ heterocycloalkenyloxy group, a substituted or unsubstituted C₃-C₃₀ heterocycloalkenylthio group, a substituted or unsubstituted C₂-C₃₀ alkynyl group, a substituted or unsubstituted C₂-C₃₀ alkynyloxy group, a substituted or unsubstituted C₂-C₃₀ alkynylthio group, a substituted or unsubstituted C₆-C₃₀ aryl group, a substituted or unsubstituted C₆-C₃₀ aryloxy group, a substituted or unsubstituted C₆-C₃₀ arylthio group, a substituted or unsubstituted C₁-C₃₀ heteroaryl group, a substituted or unsubstituted C₁-C₃₀ heteroaryloxy group, or a substituted or unsubstituted C₁-C₃₀ heteroarylthio group,
Rₐ and R_{b} are each independently hydrogen, deuterium, a hydroxyl group, a cyano group, a nitro group, a substituted or unsubstituted C₁-C₃₀ alkyl group, a substituted or unsubstituted C₁-C₃₀ alkoxy group, a substituted or unsubstituted C₁-C₃₀ alkylthio group, a substituted or unsubstituted C₃-C₃₀ cycloalkyl group, a substituted or unsubstituted C₃-C₃₀ cycloalkoxy group, or a substituted or unsubstituted C₃-C₃₀ cycloalkylthio group, and
* is a binding site with an adjacent atom of Formula 1.

4. The resist composition of claim 3, wherein, in Formula 1,
L₁₁ is O, S, C═O, or S═O, and
L₁₂ is CRₐR_{b}, O, S, C═O, or S═O,
wherein Rₐ and R_{b} are each independently hydrogen, deuterium, a hydroxyl group, a cyano group, a nitro group, a substituted or unsubstituted C₁-C₃₀ alkyl group, a substituted or unsubstituted C₁-C₃₀ alkoxy group, a substituted or unsubstituted C₁-C₃₀ alkylthio group, a substituted or unsubstituted C₃-C₃₀ cycloalkyl group, a substituted or unsubstituted C₃-C₃₀ cycloalkoxy group, or a substituted or unsubstituted C₃-C₃₀ cycloalkylthio group.

5. The resist composition of claim 3, wherein, in Formula 1,
(L₁₁)ₐ₁₁ is O, O(C═O), or O(C═O) O, and
(L₁₂)ₐ₁₂ is a single bond, CRₐR_{b}, O, C═O, O(C═O), or O(C═O) O,
wherein Rₐ and R_{b} are each independently hydrogen, deuterium, a hydroxyl group, a cyano group, a nitro group, a substituted or unsubstituted C₁-C₃₀ alkyl group, a substituted or unsubstituted C₁-C₃₀ alkoxy group, a substituted or unsubstituted C₁-C₃₀ alkylthio group, a substituted or unsubstituted C₃-C₃₀ cycloalkyl group, a substituted or unsubstituted C₃-C₃₀ cycloalkoxy group, or a substituted or unsubstituted C₃-C₃₀ cycloalkylthio group.

6. The resist composition of claim 3, wherein, in Formula 1,
X₁₁ and X₁₂ are each independently a C₁-C₃₀ alkyl group, a C₃-C₃₀ cycloalkyl group, a C₃-C₃₀ heterocycloalkyl group, a C₂-C₃₀ alkenyl group, a C₃-C₃₀ cycloalkenyl group, a C₃-C₃₀ heterocycloalkenyl group, a C₂-C₃₀ alkynyl group, a C₆-C₃₀ aryl group, a C₇-C₃₀ arylalkyl group, a C₁-C₃₀ heteroaryl group, or a C₂-C₃₀ heteroarylalkyl group, and
each of the C₁-C₃₀ alkyl group, the C₃-C₃₀ cycloalkyl group, the C₃-C₃₀ heterocycloalkyl group, the C₂-C₃₀ alkenyl group, the C₃-C₃₀ cycloalkenyl group, the C₃-C₃₀ heterocycloalkenyl group, the C₂-C₃₀ alkynyl group, the C₆-C₃₀ aryl group, the C₇-C₃₀ arylalkyl group, the C₁-C₃₀ heteroaryl group, and the C₂-C₃₀ heteroarylalkyl group is unsubstituted or substituted with deuterium, a halogen, a cyano group, a nitro group, a hydroxyl group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₃₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₁-C₂₀ heteroaryl group, a C₆-C₂₀ aryloxy group, a C₆-C₂₀ arylthio group, a C₁-C₂₀ heteroaryloxy group, a C₁-C₂₀ heteroarylthio group, or any combination thereof.

7. The resist composition of claim 3, wherein, in Formula 1, X₁₁ comprises at least one halogen.

8. The resist composition of claim 3, wherein, in Formula 1,
X₁₁ is a C₁-C₃₀ alkyl group, a C₃-C₃₀ cycloalkyl group, a C₂-C₃₀ alkenyl group, a C₃-C₃₀ cycloalkenyl group, a C₂-C₃₀ alkynyl group, a C₆-C₃₀ aryl group, or a C₇-C₃₀ arylalkyl group, and
each of the C₁-C₃₀ alkyl group, the C₃-C₃₀ cycloalkyl group, the C₂-C₃₀ alkenyl group, the C₃-C₃₀ cycloalkenyl group, the C₂-C₃₀ alkynyl group, the C₆-C₃₀ aryl group, and the C₇-C₃₀ arylalkyl group is substituted with a halogen, a C₁-C₂₀ halogenated alkyl group, a C₁-C₂₀ halogenated alkoxy group, a C₁-C₂₀ halogenated alkylthio group, or any combination thereof.

9. The resist composition of claim 1, wherein the organometallic compound represented by Formula 1 is represented by Formula 1-1: 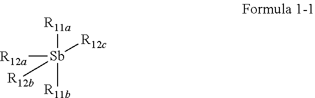
wherein, in Formula 1-1,
R₁₁ₐ and R_{11b} are each independently a linear, branched, or cyclic monovalent C₁-C₃₀ hydrocarbon group having an acid dissociation constant (pKa) of 4.5 or less and optionally containing one or more heteroatoms, and
R₁₂ₐ, R_{12b}, and R_{12c} are each independently a linear, branched, or cyclic C₁-C₃₀ monovalent hydrocarbon group optionally containing one or more heteroatoms.

10. The resist composition of claim 1, wherein the organometallic compound represented by Formula 1 is selected from Group I:

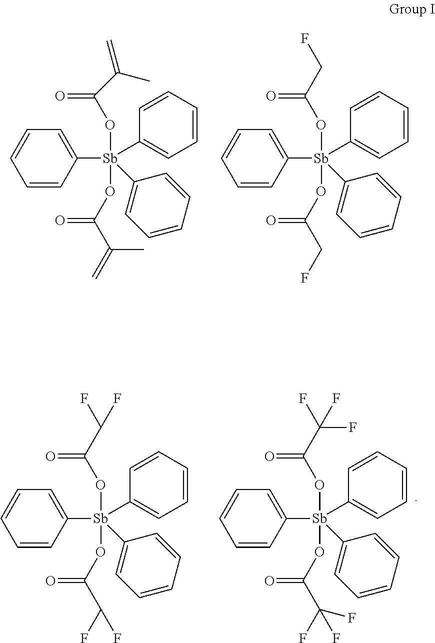

11. The resist composition of claim 1, wherein a temperature at which a mass of a sample of the organometallic compound becomes 95% of an initial mass of the sample of the organometallic compound is 180° C. or more.

12. The resist composition of claim 1, wherein the resist composition has a deterioration ratio of 10% or less after storage of the resist composition at a temperature of 40° C. for 3 weeks.

13. The resist composition of claim 1, wherein the solvent comprises an ether-based solvent, a ketone-based solvent, an amide-based solvent, an ester-based solvent, a sulfoxide-based solvent, or any combination thereof.

14. The resist composition of claim 1, wherein the solvent comprises a chain ketone-based solvent, a cyclic ketone-based solvent, a polyhydric alcohol-containing ether carboxylate-based solvent, a lactone-based solvent, an acetate ester-based solvent, or any combination thereof.

15. The resist composition of claim 1, wherein the solvent comprises cyclopentanone, cyclohexanone, cycloheptanone, propylene glycol monomethyl ether acetate, propylene glycol monoethyl ether acetate, propylene glycol monopropyl ether acetate, propylene glycol monobutyl ether acetate, or any combination thereof.

16. The resist composition of claim 1, wherein the resist composition does not comprise any or substantially any water, and the resist composition does not comprise any or substantially any polar protic organic solvent.

17. A method of forming a pattern, the method comprising:
applying the resist composition of claim 1 on a substrate to form a resist film;
exposing at least a portion of the resist film to high-energy rays to form an exposed resist film; and
developing the exposed resist film based on using a developer.

18. The method of claim 17, wherein the exposing is performed based on irradiating deep ultraviolet (DUV) rays, extreme ultraviolet (EUV) rays, and/or electron beams (EBs).

19. The method of claim 17, wherein the organometallic compound undergoes a condensation reaction based on the exposing of at least the portion of the resist film.

20. The method of claim 17, wherein
based on the exposing at least the portion of the resist film, the exposed resist film comprises an exposed portion and an unexposed portion, and
the developing the exposed resist film includes removing the unexposed portion.
